(19) United States
(12) Patent Application Publication
(10) Pub. No.: US 2017/0040948 A1
(43) Pub. Date: Feb. 9, 2017

(54) POWER AMPLIFIERS WITH TUNABLE LOADLINE MATCHING NETWORKS

(71) Applicant: TDK Corporation, Tokyo (JP)

(72) Inventor: Chris Levesque, Fountain Valley, CA (US)

(21) Appl. No.: 15/230,205

(22) Filed: Aug. 5, 2016

Related U.S. Application Data
(60) Provisional application No. 62/201,233, filed on Aug. 5, 2015.

(51) Int. Cl. H03F 1/02; H03F 3/24; H03F 1/56; H03F 3/195

(52) U.S. Cl. CPC H03F 1/0222; H03F 3/195; H03F 3/245; H03F 1/56; H03F 2200/255; H03F 2200/423; H03F 2200/171; H04B 2001/0408

(57) ABSTRACT

A power amplifier is described. The power amplifier includes at least a first power amplifier stage coupled with a power supply. The first power amplifier stage is configured to adjust a first output power of the first power amplifier stage based on a power supply voltage of the power supply. The power amplifier also includes at least a first tunable loadline matching network. The first tunable loadline matching network is configured to adjust a loadline value of the power amplifier. The first tunable loadline matching network includes at least a first set of metal oxide semiconductor variable capacitor arrays.

### CROSS-REFERENCE TO RELATED APPLICATIONS

This application claims the benefit of U.S. Provisional Application No. 62/201,233 filed on Aug. 5, 2015, which is hereby incorporated by reference in its entirety.

### FIELD

Embodiments of the invention relate to electronic systems and, in particular, to power amplifiers in radio frequency systems.

### BACKGROUND

A wireless device such as a smart phone, tablet, or laptop computer can communicate over multiple frequency bands using one or more common or shared antennas. A desire to transmit at wider bandwidth and/or over different communications networks has increased a demand for the number of bands that a wireless device can communicate over. For example, a wireless device may be specified to operate using one or more of a variety of communications standards including, for example, GSM/EDGE, IMT-2000 (3G), 4G, Long Term Evolution (LTE), Advanced LTE, IEEE 802.11 (Wi-Fi), Mobile WiMAX, Near Field Communication (NFC), Global Positioning System (GPS), GLONASS, Galileo, Bluetooth, and the like. Proprietary standards can also be applicable. The complexities of multi-band communication can be further exacerbated in configurations in which the wireless device is specified to use carrier aggregation.

### SUMMARY

A power amplifier is described. The power amplifier includes at least a first power amplifier stage coupled with a power supply. The first power amplifier stage is configured to adjust a first output power of the first power amplifier stage based on a power supply voltage of the power supply. The power amplifier also includes at least a first tunable loadline matching network. The first tunable loadline matching network is configured to adjust a loadline value of the power amplifier. The first tunable loadline matching network includes at least a first set of metal oxide semiconductor variable capacitor arrays.

Other features and advantages of embodiments of the present invention will be apparent from the accompanying drawings and from the detailed description that follows.

### BRIEF DESCRIPTION OF THE DRAWINGS

Embodiments of the present invention are illustrated by way of example and not limitation in the figures of the accompanying drawings, in which like references indicate similar elements and in which:

FIG. 1 illustrates a schematic diagram of one example of a power amplifier system with a fixed matching network;

FIG. 2 illustrates a schematic diagram of one embodiment of a power amplifier system with a tunable loadline matching network;

FIG. 3 illustrates a graph of one example of power amplifier loadline versus battery voltage and power amplifier output power;

FIG. 4 illustrates a graph of one example of normalized power added efficiency (PAE) versus power amplifier output power;

FIG. 5 illustrates a schematic diagram of one example of a power amplifier system with fixed matching networks;

FIG. 6 illustrates a schematic diagram of one embodiment of a power amplifier system with tunable loadline matching networks;

FIG. 7 illustrates a schematic diagram of a programmable filter according to an embodiment;

FIG. 8 illustrates a schematic diagram of one embodiment of an RF signal processing circuit;

FIG. 9 illustrates a schematic diagram of a matching network according to an embodiment;

FIG. 10 illustrates a schematic diagram of an integrated circuit (IC) according to one embodiment;

FIGS. 11A and 11B illustrate graphs of two examples of capacitance versus bias voltage;

FIG. 12 illustrates a schematic diagram of an IC according to another embodiment;

FIG. 13 illustrates a schematic diagram of an IC according to another embodiment;

FIG. 14A illustrates a circuit diagram of a variable capacitor cell according to one embodiment;

FIG. 14B illustrates a circuit diagram of a variable capacitor cell according to another embodiment;

FIG. 15A illustrates a circuit diagram of a variable capacitor cell according to another embodiment;

FIG. 15B illustrates a circuit diagram of a variable capacitor cell according to another embodiment;

FIG. 16A illustrates a circuit diagram of a variable capacitor cell according to another embodiment;

FIG. 16B illustrates a circuit diagram of a variable capacitor cell according to another embodiment;

FIG. 17A illustrates a circuit diagram of a variable capacitor cell according to another embodiment;

FIG. 17B illustrates a circuit diagram of a variable capacitor cell according to another embodiment;

FIG. 18A illustrates a circuit diagram of a variable capacitor cell according to another embodiment;

FIG. 18B illustrates a circuit diagram of a variable capacitor cell according to another embodiment;

FIG. 19A illustrates a circuit diagram of a variable capacitor cell according to another embodiment;

FIG. 19B illustrates a circuit diagram of a variable capacitor cell according to another embodiment;

FIG. 20A illustrates a circuit diagram of a variable capacitor cell according to another embodiment;

FIG. 20B illustrates a circuit diagram of a variable capacitor cell according to another embodiment;

FIG. 21A illustrates a circuit diagram of a variable capacitor cell according to another embodiment;

FIG. 21B illustrates a circuit diagram of a variable capacitor cell according to another embodiment;

FIG. 22A illustrates a circuit diagram of a variable capacitor cell according to another embodiment;

FIG. 22B illustrates a circuit diagram of a variable capacitor cell according to another embodiment;

FIG. 23A illustrates a circuit diagram of a variable capacitor cell according to another embodiment;

FIG. 23B illustrates a circuit diagram of a variable capacitor cell according to another embodiment;

FIG. 24A illustrates a circuit diagram of a variable capacitor cell according to another embodiment;

FIG. 24B illustrates a circuit diagram of a variable capacitor cell according to another embodiment;

FIG. 25A illustrates a circuit diagram of a variable capacitor cell according to another embodiment;

FIG. 25B illustrates a circuit diagram of a variable capacitor cell according to another embodiment;

FIG. 26A illustrates a circuit diagram of a variable capacitor cell according to another embodiment; and

FIG. 26B illustrates a circuit diagram of a variable capacitor cell according to another embodiment.

### DETAILED DESCRIPTION

Disclosed herein are power amplifiers with a tunable loadline matching network.

Power efficiency is one metric by which customers use to determine which power amplifier system to purchase, as power efficiency impacts battery life in mobile applications. There is a demand for manufacturers of power amplifier systems to continuously improve power efficiency, including both the efficiency of power amplifiers themselves and DC-to-DC converters used to generate a power amplifier supply voltage for the power amplifiers. Although improvements in fabrication processing can provide incremental improvements in power efficiency, little progress has been made on architectural and design fronts.

The challenges in improving power efficiency can be exacerbated in power amplifier systems that employ carrier aggregation to widen bandwidth. For example, in a power amplifier system operating using uplink carrier aggregation (mobile to base station), two or more power amplifiers can simultaneously transmit different waveforms associated with different frequency carriers. To provide high efficiency, envelope tracking (ET) can be employed, in which a voltage level of a power amplifier supply voltage of a power amplifier is controlled based on an envelope of an RF signal amplifier by the power amplifier. Using a shared envelope tracking DC-to-DC converter for two or more power amplifiers can be complicated to implement and/or can have a relatively low efficiency. However, using separate envelope tracking DC-to-DC converters for two or more power amplifiers can be prohibitive in cost and/or size. In one example, an envelope tracking DC-to-DC converter is relatively low in efficiency at 80 to 85%, yet a single power amplifier plus envelope converter can deliver system efficiencies (power amplifier+DC-to-DC converter) at about 40%.

Power amplifiers with tunable loadline matching networks are described herein. In certain configurations, a power amplifier includes a tunable loadline matching network implemented using one or more metal oxide semiconductor (MOS) variable capacitor arrays. Examples of MOS variable capacitor arrays can be as described in Ser. No. 14/559,783 and in U.S. Patent Publication No. 2014/0354348, each of which has been expressly incorporated by reference herein.

One or more MOS variable capacitor arrays can be used to implement a tunable matching network at the output of a power amplifier. The capacitance of the tunable matching network can be controlled by programming a capacitance value of the one or more MOS variable capacitor arrays, thereby adjusting the loadline value (real part of impedance in ohms) of the power amplifier. The capacitance of the one or more MOS variable capacitor arrays can be selected based on the output power and battery voltage of the power amplifier system using techniques including those described herein, thereby eliminating a need for a DC-to-DC converter and allowing a power amplifier to be powered directly by a battery voltage. For instance, in one example in which a power amplifier is implemented using a bipolar junction transistor, a collector of the bipolar junction transistor can be connected to the battery voltage rather than to a regulated voltage generated by a DC-to-DC converter.

As skilled artisans will appreciate, the loadline value at the output of a power amplifier impacts both the power amplifier's power-added efficiency (PAE) and the power amplifier's linearity. By controlling the capacitance of the one or more MOS variable capacitor arrays used to implement the tunable loadline matching network, the power amplifier can be operated with a desired loadline value and corresponding power amplifier performance.

In contrast, a power amplifier that operates with a fixed output matching network has a loadline that is fixed in value, such that expected output power can be delivered at a certain minimum collector voltage. For instance, a loadline value in the range of 3 to 5 ohms can be used for 2.8V operations at 30 dBm power. When such a system operates at lower output power levels, power efficiency can suffer since the loadline value is too low.

By implementing a power amplifier to have a tunable loadline matching network, power amplifier efficiency can be increased by increasing the loadline value at back-off power levels. In contrast, the loadline value cannot be increased at low output power levels in a power amplifier system that operates with a fixed output matching network.

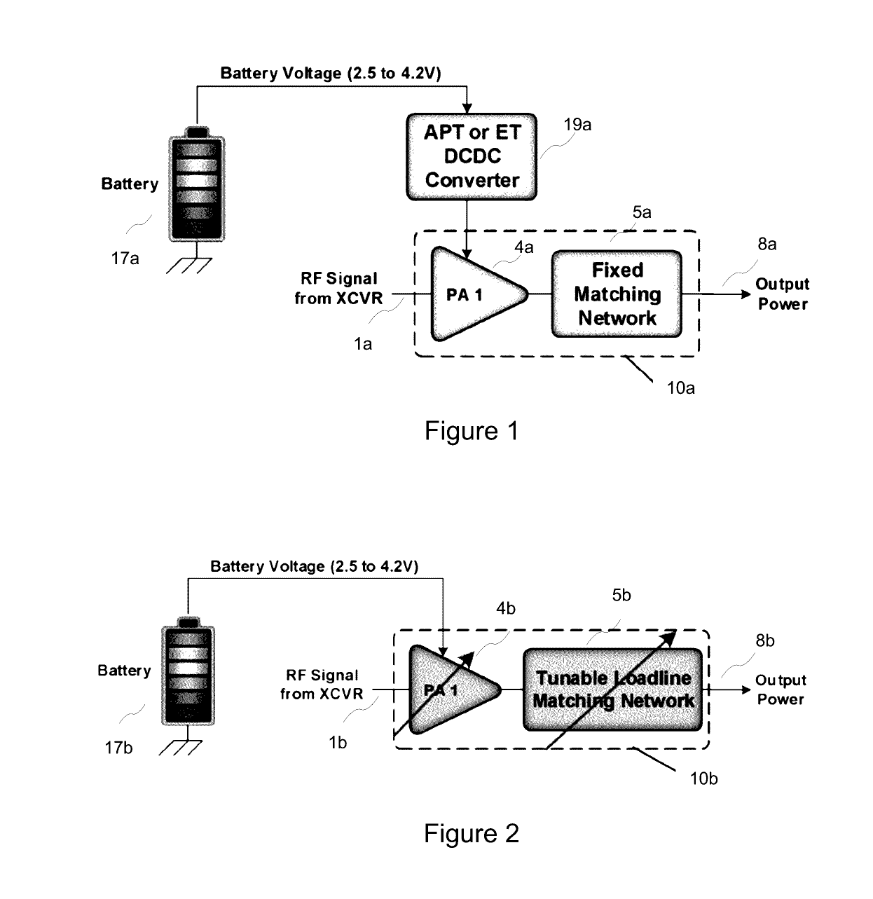

FIG. 1 is a schematic diagram of one example of a power amplifier system with a fixed matching network. The power amplifier system includes a power source, such as a battery 17a, coupled with a DC-DC power converter, such as an APT or ET DC-DC power converter 19a. The APT or ET DC-DC power converter 19a is coupled with a first power amplifier stage 4a of the power amplifier 10a. For various embodiments, a first power amplifier stage 4a is implemented using one or more bipolar junction transistors and the APT or ET DC-DC converter 19a is coupled to a collector of the one or more junction transistors. Further, first power amplifier stage 4a is configured to have an RF input 1a. The first power amplifier stage 4a is coupled with a fixed matching network 5a of the power amplifier 10a. The fixed matching network 5a is configured to have an RF output 8a.

A battery voltage of a mobile device can vary over time. Because the battery voltage varies over a wide range, the power amplifier system of FIG. 1 includes a DC-to-DC converter 19a used to generate a power amplifier voltage of a desired voltage level for the power amplifier 10a. For instance, the power amplifier 10a can be implemented using a bipolar junction transistor, and the DC-to-DC converter can be used to reduce the battery voltage to control a collector voltage of the bipolar transistor such that the power amplifier 10a operates with relatively high PAE.

The overall system efficiency of the power amplifier system of FIG. 1 can be based on a product of the efficiency of the power amplifier 10a and the efficiency of the DC-to-DC converter 19a. In one example, average power tracking (APT) is used, and the DC-to-DC converter 19a operates with an efficiency of about 92% and the power amplifier operates with an efficiency of about 40%. Thus, in this example, system efficiency is about 36%. In another example, envelope tracking (ET) is used, and DC-to-DC converter operates with an efficiency of about 83% and the power amplifier operates with an efficiency of about 52%. In this example, system efficiency is about 43%.

FIG. 2 is a schematic diagram of a power amplifier system with a tunable loadline matching network according to an embodiment. The power amplifier system includes a power source, such as a battery 17b, coupled with a tunable first power amplifier stage 4b of the power amplifier 10b. For various embodiments, a tunable first power amplifier stage 4b is implemented using one or more bipolar junction transistors and the battery 17b is coupled to a collector of the one or more junction transistors. The tunable first power amplifier stage is configured to have a bias voltage and/or bias current adjusted to achieve higher efficiency. Further, the tunable first power amplifier stage 4b is configured to have an RF input 1b. The tunable first power amplifier stage 4b is coupled with a tunable loadline matching network 5b of the power amplifier 10b. The tunable loadline matching network 5b is configured to have an RF output 8b.

For various embodiments, the power amplifier 10b of FIG. 2 includes a tunable loadline matching network, which can be implemented using one or more MOS variable capacitor arrays including those described herein.

In contrast to the power amplifier system of FIG. 1, the power amplifier system of FIG. 2 omits a DC-to-DC converter. Thus, the illustrated power amplifier system does not operate with APT or ET. Rather, the loadline value of the power amplifier 10b can be controlled based on the battery voltage and output power to provide high power amplifier efficiency. In one example, the power amplifier system achieves a power amplifier efficiency of at least 50%, for instance in the range of about 50% to about 60%. The illustrated power amplifier system can achieve a higher efficiency relative to a power amplifier system using ET or APT.

In one embodiment, a loadline voltage of a power amplifier can be expressed based on Equation 1 below, where the CollectorVoltage is the available voltage for the power amplifier (which can come be from, for instance, directly from a battery or from a DC-to-DC converter or other regulator), and the SaturationVoltage is the residual voltage across the transistor when fully turned on.

$$Loadline ( ohms ) = \frac{1000 * {( 2 * {Collector}_{Voltage} - {Saturation}_{Voltage} )}^{2}}{8 * {10}^{\frac{Output Power ( dBm )}{10}}} \qquad Equation 1$$

Although Equation 1 is described for a power amplifier implementation using bipolar transistors, the teachings herein are also applicable to power amplifiers implemented using field-effect transistors (FETs), such as complementary metal oxide semiconductor (CMOS) transistors or silicon on insulator (SOI) transistors. In such configurations, the collector voltage in Equation 1 can be replaced with a drain voltage of the FET. In one embodiment, a power amplifier is fabricated using a Gallium Nitride (GaN) process technology.

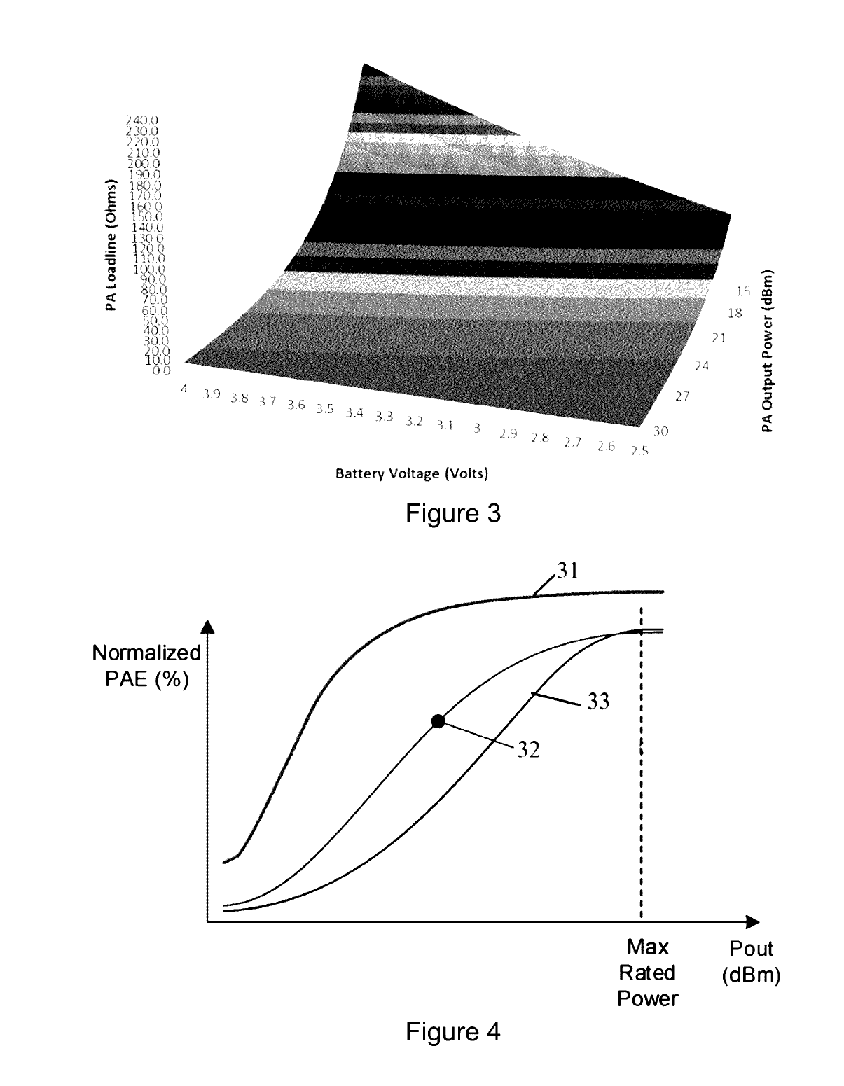

FIG. 3 is a graph of one example of power amplifier (PA) loadline versus battery voltage and power amplifier output power.

The plot illustrates loadline value versus output power and voltage as described in Equation 1 above. As shown in FIG. 3, lower voltages and higher output power yields the lowest loadline values.

FIG. 4 is a graph of one example of normalized power added efficiency (PAE) versus power amplifier output power.

In certain configurations described herein, a power amplifier operates with a programmable loadline matching network and is powered using a battery voltage according to techniques described herein. The efficiency of such a system can be enhanced in part due to the elimination of the DC-to-DC converter and in part due to the programmable aspect of the loadline. The power amplifier efficiency is increased significantly across a wide range of output power.

In the graph of FIG. 4, PAE has been normalized based on output power.

The graph includes a first plot 31 of normalized PAE versus output power for a power amplifier that receives power directly from a battery voltage and that includes a tunable loadline matching network as described herein. The graph further includes a second plot 32 of normalized PAE versus output power for a power amplifier that receives power from a DC-to-DC converter and that includes a fixed matching network. The graph further includes a third plot 33 of normalized PAE versus output power for a power amplifier that receives power directly from a battery voltage and that includes a fixed matching network.

As shown in FIG. 4, the power amplifier with the tunable loadline matching network exhibits the highest power efficiency. Although the efficiency decreases at lower output power levels, the overall efficiency of the power amplifier with the tunable loadline matching network is higher across the range of output power levels relative to either of the other power amplifier implementations.

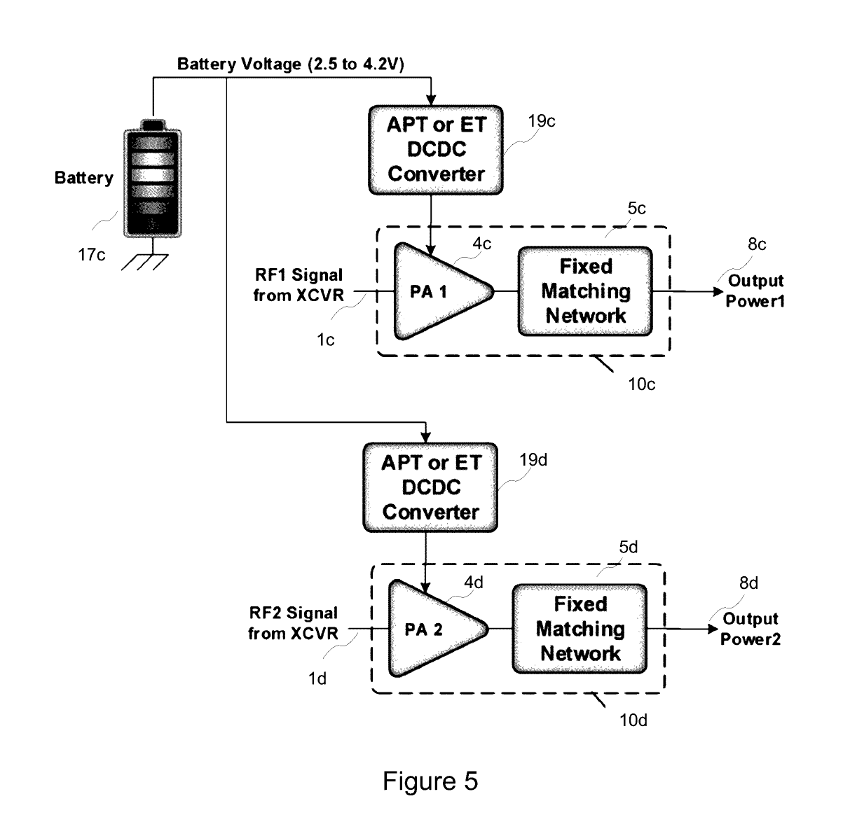

FIG. 5 is a schematic diagram of one example of a power amplifier system with fixed matching networks. The illustrated power amplifier system includes a first power amplifier 10c and a second power amplifier 10d, which can be used to provide uplink carrier aggregation. In addition, the power amplifier system includes a power source, such as a battery 17c, coupled with a first DC-DC power converter, such as a first APT or ET DC-DC power converter 19c. The first APT or ET DC-DC power converter 19c is coupled with a first power amplifier stage 4c of the first power amplifier 10c. The first power amplifier stage 4c of the first power amplifier 10c is implemented using techniques including those described herein. Further, the first power amplifier stage 4c is configured to have a first RF input 1c. The first power amplifier stage 4a of the first power amplifier 10c is coupled with a first matching network 5c of the first power amplifier 10c. The fixed matching network 5c of the first power amplifier 10c is configured to have a first RF output 8c.

The power amplifier system illustrated in FIG. 5 also includes a second DC-DC power converter, such as a second APT or ET DC-DC power converter 19d coupled with the power source, such as the battery 17c. The second APT or ET DC-DC power converter 19d is coupled with a first power amplifier stage 4d of the second power amplifier 10d. The first power amplifier stage 4d of the second power amplifier 10d is implemented using techniques including those described herein. Further, the first power amplifier stage 4d of the second power amplifier 10d is configured to have a second RF input 1d. The first power amplifier stage 4d of the second power amplifier 10d is coupled with a first matching network 5d of the first power amplifier 10d. The fixed matching network 5d is configured to have a second RF output 8d.

In the illustrated configuration each of the power amplifiers 10c, 10d receives a power amplifier voltage from a separate DC-to-DC converter 19c, 19d, which can operate using ET or APT. Such an implementation can be require a relatively large area on an integrated circuit (for instance 15 to 25 mm2) and/or expensive.

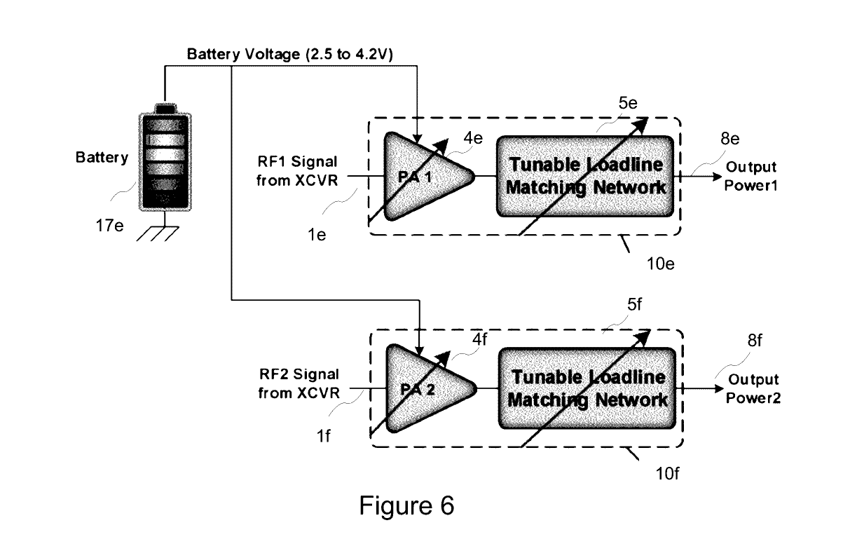

FIG. 6 is a schematic diagram of one embodiment of a power amplifier system with tunable loadline matching networks. The illustrated power amplifier system includes a first power amplifier 10e and a second power amplifier 10f, which can be used to provide uplink carrier aggregation.

The power amplifier system illustrated in FIG. 6 includes a power source, such as a battery 17e, coupled with a tunable first power amplifier stage 4e of the first power amplifier 10e. The tunable first power amplifier stage 4e of the first power amplifier 10e is implemented using techniques including those described herein. The tunable first power amplifier stage 4e is configured to have a bias voltage and/or bias current adjusted to achieve higher efficiency. Further, the tunable first power amplifier stage 4e is configured to have a first RF input 1e. The tunable first power amplifier stage 4e is coupled with a tunable loadline matching network 5e of the power amplifier 10e. The tunable loadline matching network 5e of the first power amplifier 10e is configured to have a first RF output 8e.

The power amplifier system illustrated in FIG. 6 also includes a tunable first power amplifier stage 4f of the second power amplifier 10f coupled with the power source, such as a battery 17e. The tunable first power amplifier stage 4f of the second power amplifier 10f is implemented using techniques including those described herein. The tunable first power amplifier stage 4f of the second power amplifier 10f is configured to have a bias voltage and/or bias current adjusted to achieve higher efficiency. Further, the tunable first power amplifier stage 4e of the second power amplifier 10f is configured to have a second RF input 1f. The tunable first power amplifier stage 4f of the second power amplifier 10f is coupled with a tunable loadline matching network 5f of the second power amplifier 10f. The tunable loadline matching network 5f of the second power amplifier 10f is configured to have a second RF output 8f.

In contrast to the power amplifier system of FIG. 5, the power amplifier system of FIG. 6 omits the DC-to-DC converters in favor of controlling power efficiency by tuning the loadline values of the power amplifiers 10e, 10f. As described earlier each of the illustrated tunable loadline matching networks 5e, 5f can be implemented using one or more MOS variable capacitor arrays as described herein.

The illustrated power amplifier system provides a high efficiency transmitter for uplink carrier aggregation while reducing cost and/or area on an integrated circuit relative to the configuration of FIG. 5.

In certain configurations, a power amplifier can include two or power amplifier stages and one or more interstage matching networks to provide impedance matching between the power amplifier stages. In such configurations, the interstage impedance matching can additionally and/or alternatively be tuned using one or more MOS variable capacitor arrays.

Furthermore, power amplifier bias voltage and/or bias current can be adjusted to achieve higher efficiency. Additionally, one or more harmonic termination circuits at the output of the power amplifier can be implemented using MOS variable capacitor arrays, which can be controlled to provide output harmonic tuning.

Such tuning features of power amplifier circuitry are graphically illustrated using an arrow in the PA symbol for the power amplifier 4b of FIG. 2 and by using arrows in the PA symbol for the power amplifiers 4e, 4f of FIG. 6.

Depending on the efficiency targets and the solution size, not all tuning features may be used and any combinations can be selected to achieve a desired performance.

The teachings herein can be used to eliminate a need for a DC-to-DC converter for both ET and APT power amplifier systems. Eliminating a DC-to-DC converter can increase system efficiency for a range of transmit output power levels and battery voltages to create an efficient power amplifier for LTE single carrier and uplink carrier aggregation. The teachings herein can enable handsets to support uplink carrier aggregation cost effectively and efficiently. Eliminating the DC-to-DC converter(s) and/or ET or APT can simplify transmitter calibration of handsets, which can reduce cost and/or complexity.

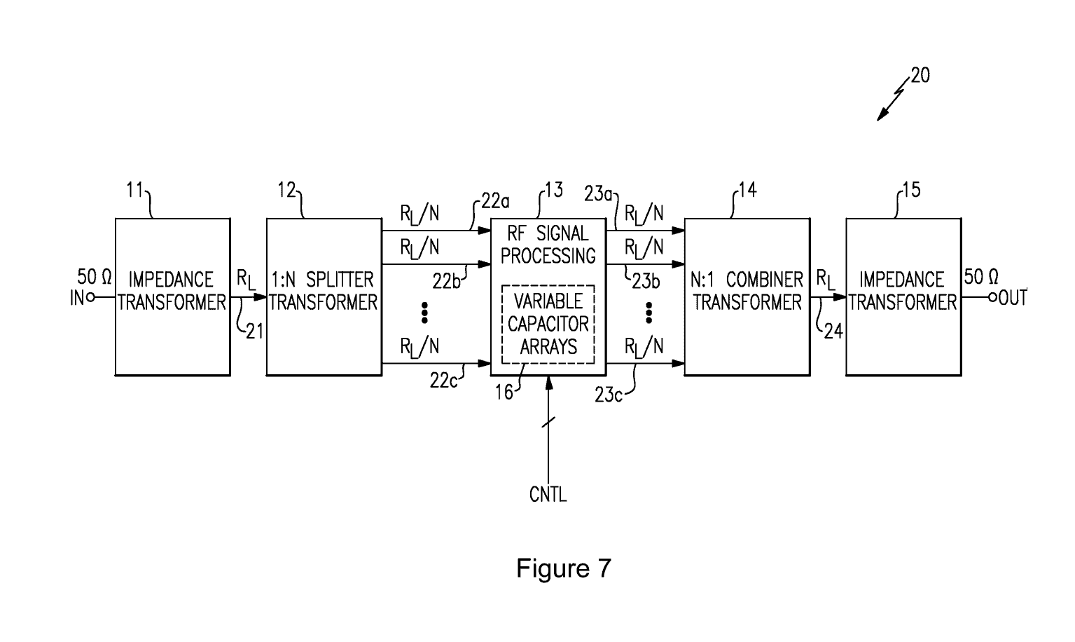

FIG. 7 is a schematic diagram of a programmable filter 20 according to one embodiment. The programmable filter 20 includes an input impedance transformer 11, a splitter transformer 12, an RF signal processing circuit 13, a combiner transformer 14, and an output impedance transformer 15. The programmable filter 20 further includes an RF input IN and an RF output OUT. For various embodiments, the programmable filter 20 is configured as a tunable filter including those described herein.

The input impedance transformer 11 can receive an RF input signal on the RF input IN, and can generate an impedance transformed signal 21. The input impedance transformer 11 can provide an impedance transformation from input to output. For example, in one embodiment, the input impedance transformer 11 transforms an input impedance of about 50Ω to an output impedance of about R_{L}, where R_{L} is less than 50Ω, for example, 8Ω.

Transforming the input impedance of the programmable filter 20 in this manner can result in the impedance transformed signal 21 having a smaller voltage level relative to a voltage level of the RF input signal received at the RF input IN. For example, when the programmable filter 20 has an input impedance of about 50Ω, the voltage level of the impedance transformed signal 21 can be smaller than the voltage level of the RF input signal by a factor of about \sqrt{50/R_{L}}.

The splitter transformer 12 can receive the impedance transformed signal 21 from the input impedance transformer 11, and can generate N split signals, where N is an integer greater than or equal to 2. In the illustrated configuration, the splitter transformer 12 generates a first split signal 22a, a second split signal 22b, and a third split signal 22c. Although an example with N=3 has been illustrated, the principles and advantages disclosed herein are applicable to a broad range of values for the integer N, including 2, 3, 4, 5, or 6 or more.

Splitting the impedance transformed signal 21 into N split signals can further decrease a voltage level of the RF input signal by a factor of N. Including the splitter transformer 12 can also reduce the impedance by a factor of N. For example, when the output impedance of the input impedance transformer 11 has a value of R_{L}, the output impedance of each output of the splitter transformer 12 can have a value of R_{L}/N.

As shown in FIG. 7, the RF signal processing circuit 13 can receive the first, second, and third split signals 22a-22c, and can generate first, second, and third processed RF signals 23a-23c, respectively. As illustrated in FIG. 7, the RF signal processing circuit 13 includes variable capacitor arrays 16, which can be used to control a filtering characteristic of the RF signal processing circuit 13. The RF signal processing circuit 13 further receives a control signal CNTL, which can be used to control the capacitances of the variable capacitor arrays 16.

The illustrated RF signal processing circuit 13 can be used to process the split signals 22a-22c generated by the splitter transformer 12 to generate the processed signals 23a-23c, respectively. In certain configurations, the RF signal processing circuit 13 can include substantially identical circuitry in the signal paths between the RF signal processing circuit's inputs and outputs.

The combiner transformer 14 receives the processed signals 23a-23c, which the combiner transformer 14 can combine to generate a combined signal 24. The combiner transformer 14 can also provide an impedance transformation. For example, in a configuration in which each output of the RF signal processing circuit 13 has an output impedance of about R_{L}/N, the combiner transformer 14 can have an output impedance of about R_{L}.

The output impedance transformer 15 receives the combined signal 24 from the combiner transformer 14, and generates the RF output signal on the RF output OUT. In certain configurations, the combiner transformer 14 can have an output impedance R_{L} that is less than 50Ω, and the output impedance transformer 15 can be used to provide the RF output signal at an output impedance of about 50Ω.

The illustrated programmable filter 20 provides filtering using the RF signal processing circuit 13, which processes the split signals 22a-22c at lower impedance relative to the programmable filter's input impedance. Thereafter, the processed signals 23a-23c are combined and transformed up in impedance. For example, in one embodiment, the programmable filter's output impedance is about equal to the programmable filter's input impedance.

Configuring the programmable filter 20 to process an RF input signal in this manner can increase the programmable filter's voltage handling capability. For example, when the programmable filter 20 has an input impedance of about 50Ω, the voltage level of the RF input signal can be decreased by a factor of about N\sqrt{50/R_{L}} before it is provided to the RF signal processing circuit 13, which may include circuitry that is sensitive to high voltage conditions. Accordingly, the illustrated programmable filter 20 can be used to process high voltage RF input signals and/or can have enhanced robustness to variations in voltage standing wave ratio (VWSR).

Furthermore, configuring the programmable filter 20 to process the RF signal at lower impedance can enhance the programmable filter's linearity. In one embodiment, the illustrated configuration can reduce the third-order inter-modulation distortion (IMD3) by a factor of about 40 log₁₀ N\sqrt{50/R_{L}} relative to a configuration in which an RF input signal is provided directly to an RF signal processing circuit without impedance transformation or splitting. In one illustrative example, N can be selected to be equal to 8 and R_{L} can be selected to be about equal to about 8Ω, and the programmable filter can provide a linearity improvement of about 52 dB. However, other configurations are possible.

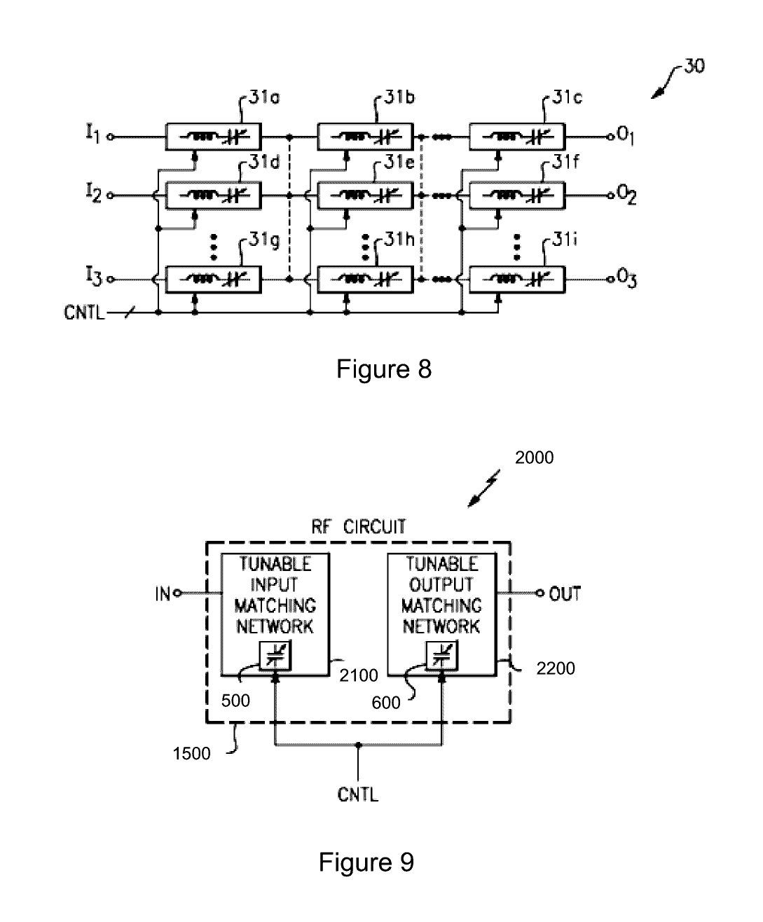

FIG. 8 is a schematic diagram of one embodiment of an RF signal processing circuit 30. The RF signal processing circuit 30 includes a first inductor-capacitor (LC) circuit 31a, a second LC circuit 31b, a third LC circuit 31c, a fourth LC circuit 31d, a fifth LC circuit 31e, a sixth LC circuit 31f, a seventh LC circuit 31g, an eighth LC circuit 31h, and a ninth LC circuit 31i. The RF signal processing circuit 30 illustrates one embodiment of the RF signal processing circuit 13 of FIG. 8.

As shown in FIG. 9, the first, second, and third LC circuits 31a-31c are arranged in a cascade between a first RF input I₁ and a first RF output O₁. Additionally, the fourth, fifth, and sixth LC circuits 31d-31f are arranged in a cascade between a second RF input I₂ and a second RF output O₂. Furthermore, the seventh, eighth, and ninth LC circuits 31g-31i are arranged in a cascade between a third RF input I₃ and a third RF output O₃.

Although FIG. 9 illustrates a configuration including three RF inputs and three RF outputs, the RF signal processing circuit 30 can be adapted to include more or fewer inputs and outputs.

The RF signal processing circuit 30 can be used to process RF input signals received on the first to third RF inputs I₁-I₃ to generate RF output signals on the first to third RF outputs O₁-O₃. As shown in FIG. 9, the RF signal processing circuit 30 receives a control signal CNTL, which can be used to control one or more variable capacitances associated with the first to ninth LC circuits 31a-31i. By controlling the LC circuits' capacitances, the control signal CNTL can be used to tune a frequency response of the RF signal processing circuit 30.

In one embodiment, the RF signal processing circuit 30 is configured to operate as a filter using techniques including those known in the art, and the control signal CNTL can be used to control a location in frequency of the filter's passband. However, other configurations are possible.

Although FIG. 9 illustrates a configuration including three LC circuits arranged in a cascade between each input and output, more or fewer LC circuits and/or other processing circuitry can be included.

Cascading LC circuits can increase a voltage handling capability of an RF signal processing circuit by limiting a voltage drop across individual circuit components of the LC circuits. For example, in certain implementations, the LC circuits 31a-31i are implemented using MOS capacitors, which can be damaged by large gate-to-drain and/or gate-to-source voltages. By arranging two or more LC circuits in a cascade, a voltage drop across the MOS capacitors during operation can be increased relative to a configuration including a single LC circuit between a particular input and output.

The RF signal processing circuit 30 illustrates one embodiment of the RF signal processing circuit 13 of FIG. 7. For example, in certain configurations, the first to third input RF inputs I₁-I₃ can receive the first to third RF split signals 22a-22c, respectively, and the first to third RF outputs O₁-O₃ can generate the first to third processed signals 23a-23c, respectively.

The RF signal processing circuit 30 includes a first signal path between the first RF input I₁ and the first RF output O₁, a second signal path between the second RF input I₂ and the second RF output O₂, and a third signal path between the third RF input I₃ and the third RF output O₃. In certain configurations, one or more electrical connections can be provided between corresponding positions along the first to third signals paths. For example, in certain implementations, the RF signal processing circuit 30 is used to process substantially identical RF input signals received on the first to third RF inputs I₁-I₃, respectively, to generate substantially identical RF output signals on the first to third RF outputs O₁-O₃. In such configurations, electrical connections can be provided along corresponding positions of signal paths, since the corresponding positions should have substantially the same voltage level. Examples of such electrical connections are illustrated in FIG. 8 with dashed lines.

FIG. 9 is a schematic diagram of another embodiment of an RF system 2000, such as a PA described herein, that includes an RF circuit 1500. The RF circuit 1500 includes a first tunable matching network 2100 electrically connected to an RF input IN and a second tunable matching network 2200 electrically connected to an RF output OUT. As shown in FIG. 9, the first tunable network 2100 and the second tunable matching network 2200 include first and second variable capacitor arrays 500, 600, respectively. The tunable matching networks may be implemented as inter-stage matching networks in a PA system as described herein.

The first variable capacitor array 500 receives the control signal CNTL, which can be used to control the first variable capacitor array's capacitance. The capacitance of the first variable capacitor array 500 can be used to control, for example, an input impedance of the RF circuit 1500 and/or to control a ratio of impedance transformation provided by the tunable input matching network 2100. Additionally, the capacitance of the second variable capacitor array 600 can be controlled by the control signal CNTL, thereby controlling, for example, an output impedance of the RF circuit 1500 and/or a ratio of impedance transformation provided by the tunable output matching network 2200.

In one embodiment, the control signal CNTL is received over an interface, such as a serial peripheral interface (SPI) or Mobile Industry Processor Interface radio frequency front end (MIPI RFFE) interface. Although two examples of interfaces have been provided, other interfaces can be used. Although FIG. 9 illustrates the first and second variable capacitor arrays 500, 600 as receiving a common control signal CNTL, other configurations are possible, such as implementations in which the first and second variable capacitor arrays 500, 600 are controlled using separate control signals.

Including the tunable input matching network 2100 and the tunable output matching network 2200 can enhance performance in a variety of ways, such as improving performance under varying voltage standing wave ratio (VSWR). The first and second variable capacitor arrays 500, 600 can be implemented in accordance with the teachings herein to provide high RF voltage handling capabilities, high Q-factor, low insertion loss, and/or high linearity.

As described above, various embodiments of a filter and various embodiments of a matching network include one or more metal oxide semiconductor (MOS) variable capacitor arrays. For various embodiments, a variable capacitor array includes a plurality of variable capacitor cells electrically connected in parallel. Each of the variable capacitor cells can include a cascade of two or more pairs of anti-series metal oxide semiconductor (MOS) capacitors between an RF input and an RF output. The pairs of anti-series MOS capacitors include a first MOS capacitor and a second MOS capacitor electrically connected in anti-series. A bias voltage generation circuit generates bias voltages for biasing the MOS capacitors of the MOS variable capacitor cells.

A MOS capacitor, according to various embodiments, includes a gate that operates as an anode, and a source and drain that are electrically connected to one another and operate as a cathode. Additionally, a DC bias voltage between the MOS capacitor's anode and cathode can be used to control the MOS capacitor's capacitance. In certain configurations, two or more pairs of anti-series MOS capacitors are cascaded to operate as a variable capacitor cell. As used herein, a pair of MOS capacitors can be electrically connected in anti-series or inverse series when the pair of MOS capacitors is electrically connected in series with the first and second MOS capacitors' anodes electrically connected to one another or with the first and second MOS capacitors' cathodes electrically connected to one another.

The variable capacitor arrays disclosed herein can exhibit high RF signal handling and/or power handling capabilities. For example, including two or more pairs of anti-series MOS capacitors in a cascade can facilitate handling of RF signals with relatively large peak-to-peak voltage swings by distributing the RF signal voltage across multiple MOS capacitors. Thus, the variable capacitor array can handle RF signals of large voltage amplitude and/or high power without overvoltage conditions that may otherwise cause transistor damage, such as gate oxide punch through.

In certain configurations, the bias voltage generation circuit can bias the MOS capacitors of a particular variable capacitor cell at a voltage level selected from a discrete number of two or more bias voltage levels associated with high linearity. Thus, rather than biasing the MOS capacitors at a bias voltage level selected from a continuous tuning voltage range, the bias voltage generation circuit generates the MOS capacitors' bias voltages by selecting a particular cell's bias voltage level from a discrete set of bias voltage levels associated with high linearity. In one embodiment, the bias voltage generation circuit biases a particular MOS capacitor either at a first bias voltage level associated with an accumulation mode of the MOS capacitor or at a second bias voltage level associated an inversion mode of the MOS capacitor.

As used herein and as persons having ordinary skill in the art will appreciate, the terms MOS capacitors refer to any types of capacitors made from transistors with insulated gates. These MOS capacitors can have gates made from metals, such as aluminum, and dielectric regions made out of silicon oxide. However, these MOS capacitors can alternatively have gates made out of materials that are not metals, such as poly silicon, and can have dielectric regions implemented not just with silicon oxide, but with other dielectrics, such as high-k dielectrics. In certain embodiments, the MOS capacitors are implemented using fabricated using silicon on insulator (SOI) processes. For example, an integrated circuit can include a support substrate, a buried oxide (BOX) layer over the support substrate, and a device layer over the BOX layer, and the MOS capacitors can be fabricated in the device layer.

In certain embodiments, a variable capacitor array omits any switches in the signal path between the variable capacitor array's RF input and RF output. Switches can introduce insertion loss, degrade Q-factor, and/or decrease linearity. Thus, rather than providing capacitance tuning by opening and closing switches to set a number of active capacitors from a capacitor bank, capacitance tuning can be provided by biasing MOS capacitors of the variable capacitor cells at different bias voltage levels to provide a desired overall capacitance of the variable capacitor array. In certain configurations, the variable capacitor cells of the variable capacitor array can have the same or different weights or sizes, and the variable capacitor array's overall capacitance is based on a linear combination of the capacitances of the variable capacitor cells.

The variable capacitor arrays herein can have high RF voltage handling capability, while having a relatively small size, a relatively high Q-factor, a relatively high linearity, and/or a relatively low insertion loss. Furthermore, in certain implementations, a variable capacitor array can provide sufficient tuning range to provide filtering across a variety of different frequency bands. Accordingly, the variable capacitor array may be used to provide frequency tuning in a wide range of RF electronics, including, for example, programmable filters, programmable resonators, programmable antenna tuners, programmable impedance matching networks, programmable phase shifters, and/or programmable duplexers.

A wireless device such as a smart phone, tablet, or laptop computer can communicate over multiple frequency bands using one or more common or shared antennas. A desire to transmit at wider bandwidth and/or over different communications networks has increased a demand for the number of bands that a wireless device can communicate over. For example, a wireless device may be specified to operate using one or more of a variety of communications standards including, for example, GSM/EDGE, IMT-2000 (3G), 4G, Long Term Evolution (LTE), Advanced LTE, IEEE 802.11 (Wi-Fi), Mobile WiMAX, Near Field Communication (NFC), Global Positioning System (GPS), GLONASS, Galileo, Bluetooth, and the like. Proprietary standards can also be applicable. The complexities of multi-band communication can be further exacerbated in configurations in which the wireless device is specified to use carrier aggregation.

The metal oxide semiconductor (MOS) capacitors, which can offer enhanced performance over certain other tunable capacitance structures. For instance, certain microelectromechanical systems (MEMS) capacitors can exhibit low Q-factor, poor reliability, and/or limited tuning range. Additionally, other approaches such as coupled resonators can suffer from large size and/or cost, and thus can be unsuitable for certain applications, including smart phones.

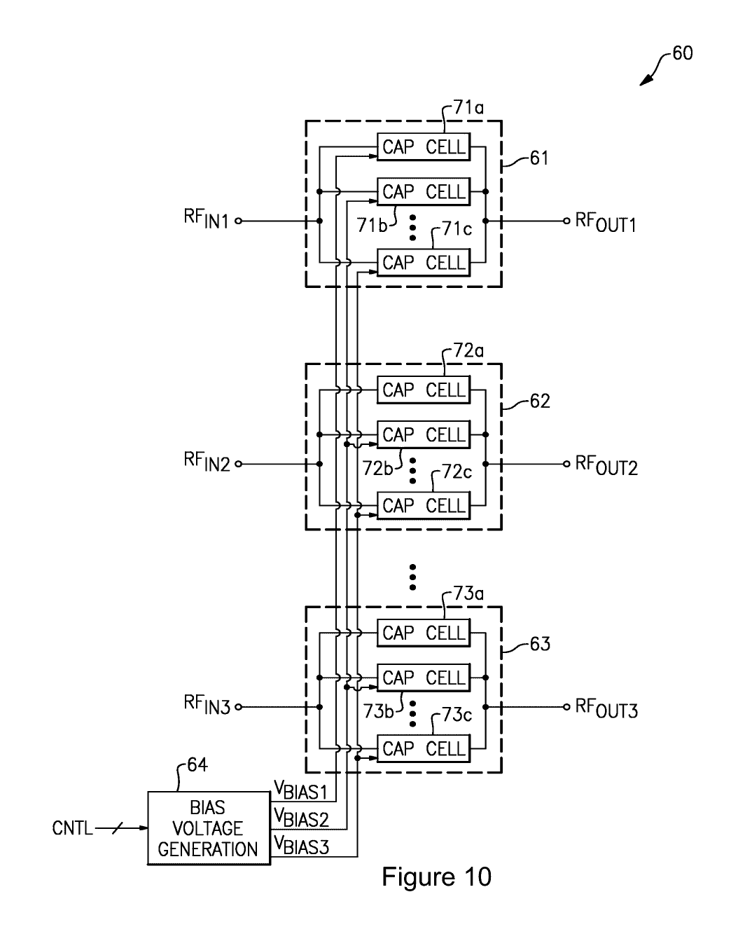

FIG. 10 is a schematic diagram of an integrated circuit (IC) 60 according to one embodiment. The IC 60 includes a first variable capacitor array 61, a second variable capacitor array 62, a third variable capacitor array 63, and a bias voltage generation circuit 64. The IC 60 includes a first RF input RF_{IN1}, a second RF input RF_{IN2}, a third RF input RF_{IN3}, a first RF output RF_{OUT1}, a second RF output RF_{OUT2}, and a third RF output RF_{OUT3}.

The first variable capacitor array 61 includes a first variable capacitor cell 71a, a second variable capacitor cell 71b, and a third variable capacitor cell 71c. The first to third capacitors cells 71a-71c are electrically connected in parallel between the first RF input RF_{IN1} and the first RF output RF_{OUT1}. The second variable capacitor array 62 includes a first variable capacitor cell 72a, a second variable capacitor cell 72b, and a third variable capacitor cell 72c. The first to third capacitors cells 72a 72c are electrically connected in parallel between the second RF input RF_{IN2} and the second RF output RF_{OUT2}. The third variable capacitor array 63 includes a first variable capacitor cell 73a, a second variable capacitor cell 73b, and a third variable capacitor cell 73c. The first to third capacitors cells 73a 73c are electrically connected in parallel between the third RF input RF_{IN3} and the third RF output RF_{OUT3}.

Although FIG. 10 illustrates the IC 60 as including three variable capacitor arrays, the IC 60 can be adapted to include more or fewer variable capacitor arrays. In one embodiment, the IC 60 can include between about 4 and about 16 variable capacitor arrays. In another embodiment, the IC 60 includes between about 1 and about 3 variable capacitor arrays. However, other configurations are possible.

Additionally, although FIG. 10 illustrates each variable capacitor array as including three variable capacitor cells, the variable capacitor arrays can be adapted to include more or fewer variable capacitor cells. In one embodiment, the IC 60 includes between about 6 and about 12 variable capacitor cells. However, a variable capacitor array can be adapted to include other numbers of variable capacitor cells.

The bias voltage generation circuit 64 receives the control signal CNTL, and generates a first bias voltage V_{BIAS1}, a second bias voltage V_{BIAS2}, and a third bias voltage V_{BIAS3}. As shown in FIG. 10, the first bias voltage V_{BIAS1} is provided to the first variable capacitor cell 71a of the first variable capacitor array 61, to the first variable capacitor cell 72a of the second variable capacitor array 62, and to the first variable capacitor cell 73a of the third variable capacitor array 63. Additionally, the second bias voltage V_{BIAS2} is provided to the second variable capacitor cell 71b of the first variable capacitor array 61, to the second variable capacitor cell 72b of the second variable capacitor array 62, and to the second variable capacitor cell 73b of the third variable capacitor array 63. Furthermore, the third bias voltage V_{BIAS3} is provided to the third variable capacitor cell 71c of the first variable capacitor array 61, to the third variable capacitor cell 72c of the second variable capacitor array 62, and to the third variable capacitor cell 73c of the third variable capacitor array 63.

The bias voltage generation circuit 64 can be used to control the voltage levels of the first, second, and third bias voltages V_{BIAS1}-V_{BIAS3} to control the capacitances of the first to third variable capacitor arrays 61-63.

The illustrated variable capacitor cells can be implemented using MOS capacitors. For example, in certain configurations, two or more pairs of anti-series MOS capacitors are cascaded to operate as a variable capacitor cell. Additionally, the first to third bias voltages V_{BIAS1}-V_{BIAS3} can be used to bias the MOS capacitors at two or more bias voltages associated with a small amount of capacitance variation, and thus with high linearity. For example, in one embodiment, the first to third bias voltages V_{BIAS1} V_{BIAS3} can be selectively controlled to bias the MOS capacitors in accumulation or inversion to control the overall capacitance of the arrays.

In certain configurations, the MOS capacitors can be fabricated using silicon on insulator (SOI) processes. However, other configurations are possible, including, for example, implementations in which the MOS capacitors are fabricated using deep sub-micron (DSM) complementary metal oxide semiconductor (CMOS) processes.

In certain configurations herein, a variable capacitor cell can include pairs of MOS capacitors implemented using anti-series configurations. Configuring a variable capacitor cell in this manner can help cancel the second-order intermodulation tones (IM2) and/or control the variation in the cell's capacitance in the presence of RF signals.

As shown in FIG. 10, the bias voltage generation circuit 64 receives the control signal CNTL, which can be used to select the voltage levels of the first, second, and third bias voltages V_{BIAS1}-V_{BIAS3}. In certain configurations, each of the variable capacitor arrays 61-63 includes weighted banks of capacitors cells. For example, in one embodiment, the first variable capacitor cell 71a, the second variable capacitor cell 71b, and the third variable capacitor cell 71c have different capacitance weights or sizes. For example, the variable capacitor cells of a particular variable capacitor array can increase in size by a scaling factor, such as 2.

The IC 60 includes a first signal path from the first RF input RF_{IN1} to the first RF output RF_{OUT1} through the first variable capacitor array 61. Additionally, the IC 60 includes a second signal path from the second RF input RF_{IN2} to the second RF output RF_{OUT2} through the second variable capacitor array 62, and a third signal path from the third RF input RF_{IN3} to the third RF output RF_{OUT3} through the third variable capacitor array 63.

In certain embodiments, the IC 60 does not include any switches in the signal paths between the IC's inputs and outputs through the variable capacitor arrays. By configuring the variable capacitor arrays in this manner, the variable capacitor arrays can have lower insertion loss and/or higher linearity relative to a configuration in which capacitance is provided by selecting discrete capacitors via switches.

As shown in FIG. 10, multiple variable capacitor arrays can be fabricated on a common IC, and can share control signals but receive different RF signals. However, other configurations are possible, such as implementations in which the variable capacitor arrays receive separate control signals.

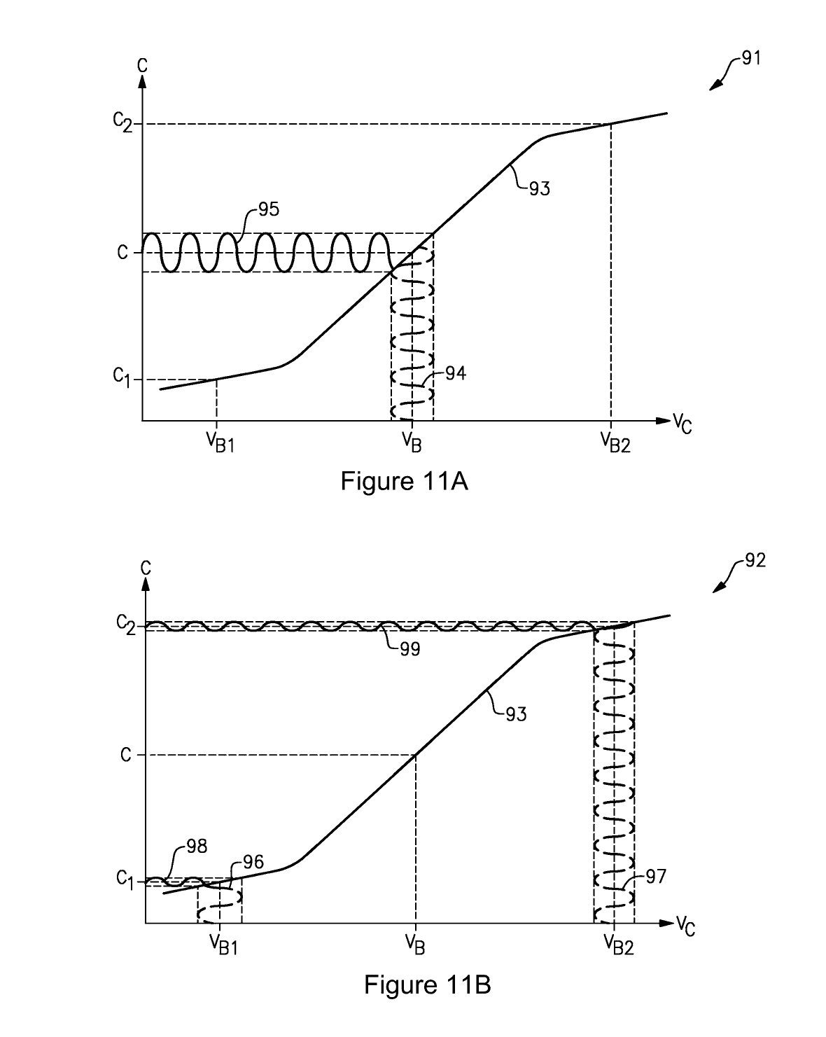

FIGS. 11A and 11B are graphs of two examples of capacitance versus bias voltage. FIG. 11A includes a first graph 91 of capacitance versus voltage, and FIG. 11B includes a second graph 92 of capacitance versus voltage.

The first graph 91 includes a high frequency capacitance-voltage (CV) plot 93 for one example of an n-type MOS capacitor. As shown in the CV plot 93, the capacitance of the MOS capacitor can increase with bias voltage level. The increase in capacitance can be associated with the MOS capacitor transitioning between operating regions or modes. For example, at low bias voltage levels, the MOS capacitor can operate in an accumulation mode in which a majority carrier concentration near the gate dielectric/semiconductor interface is greater than a background majority carrier concentration of the semiconductor. Additionally, as the voltage level of the bias voltage increases, the MOS capacitor can transition from the accumulation mode to a depletion mode in which minority and majority carrier concentrations near the gate dielectric/semiconductor interface are less than the background majority carrier concentration. Furthermore, as the voltage level of the bias voltage further increases, the MOS capacitor can transition from the depletion mode to an inversion mode in which the minority carrier concentration near the gate dielectric/semiconductor interface is greater than the background majority carrier concentration.

The first graph 91 has been annotated to include an AC signal component 94 when biasing the MOS capacitor at a bias voltage level VB. When the AC signal component 94 is not present, the MOS capacitor can have a capacitance C. However, as shown by in FIG. 11A, the AC signal component 94 can generate a capacitance variation 95. The capacitance variation 95 can be associated with a capacitance variation generated by the AC signal component 94.

With reference to FIG. 11B, the second graph 92 includes the CV plot 93, which can be as described above. The second graph 92 has been annotated to include a first AC signal component 96 associated with biasing the MOS capacitor at a first bias voltage level V_{B1}, and a second AC signal component 97 associated with biasing the MOS capacitor at a second bias voltage level V_{B2}.

As shown in FIG. 11B, the first AC signal component 96 can generate a first capacitance variation 98, and the second AC signal component 97 can generate a second capacitance variation 99.

When biased at the first bias voltage level V_{B1} or the second bias voltage level V_{B2}, the MOS capacitor can nevertheless have a capacitance that varies in the presence of AC signals. However, the first and second bias voltage levels V_{B1}, V_{B2} can be associated with DC bias points of the MOS capacitor having relatively small capacitance variation or change.

Accordingly, in contrast to the capacitance variation 95 of FIG. 11A which has a relatively large magnitude, the first and second capacitance variations 98, 99 of FIG. 11B have a relatively small magnitude.

In certain embodiments herein, a variable capacitor array includes MOS capacitors that are biased at bias voltages associated with small capacitance variation. By biasing the MOS capacitors in this manner, a variable capacitor array can exhibit high linearity.

Such a variable capacitor array can also have less capacitance variation when operated in a system using multiple frequency bands. For example, when included in a tunable filter, or a tunable matching network, the variable capacitor array can provide relatively constant capacitance even when tuned to frequency bands that are separated by a wide frequency.

In certain embodiments, the first bias voltage level V_{B1} is selected to operate in the MOS capacitor in an accumulation mode, and the second bias voltage level V_{B2} is selected to operate the MOS capacitor in an inversion mode. In certain configurations, biasing a MOS capacitor in this manner can achieve a capacitance tuning range of 3:1 or more. However, other tuning ranges can be realized, including, for example, a tuning range associated with a particular manufacturing process used to fabricate the MOS capacitor.

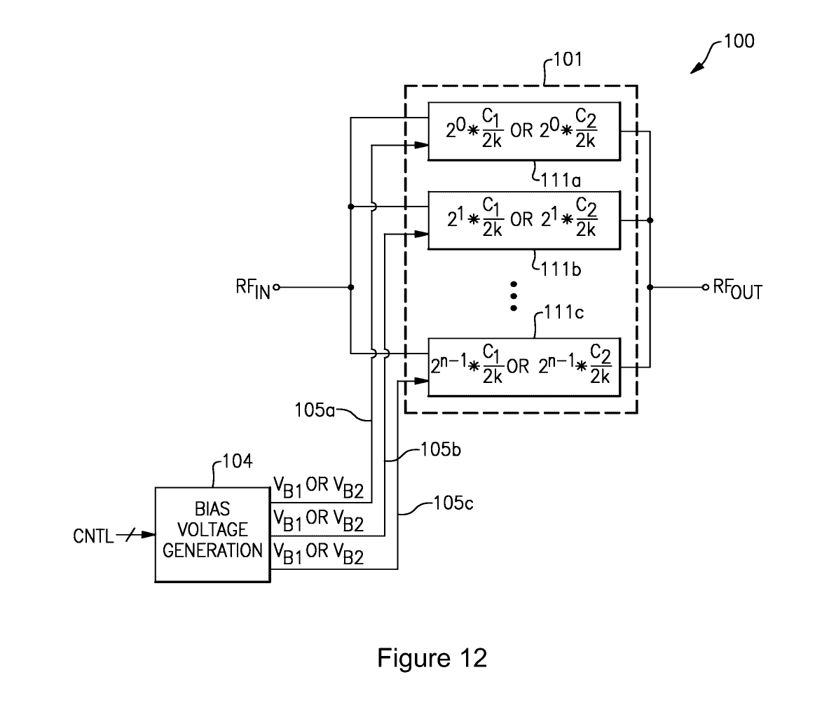

FIG. 12 is a schematic diagram of an IC 100 according to another embodiment. The IC 100 includes a variable capacitor array 101 and a bias voltage generation circuit 104. Although FIG. 12 illustrates a configuration in which the IC 100 includes one variable capacitor array, the IC 100 can be adapted to include additional variable capacitor arrays and/or other circuitry.

The variable capacitor array 101 includes a first variable capacitor cell 111a, a second variable capacitor cell 111b, and a third variable capacitor cell 111c, which have been electrically connected in parallel between an RF input RF_{IN} and an RF output RF_{OUT}. Although the illustrated variable capacitor array 101 includes three variable capacitor cells, the variable capacitor array 101 can be adapted to include more or fewer variable capacitor cells.

The bias voltage generation circuit 104 receives the control signal CNTL, and generates a first bias voltage 105a for the first variable capacitor cell 111a, a second bias voltage 105b for the second variable capacitor cell 111b, and a third bias voltage 105c for the third variable capacitor cell 111c.

In the illustrated configuration, the control signal CNTL can be used to set the voltage level of the first bias voltage 105a to a first bias voltage level V_{B1} or to a second bias voltage level V_{B2}. Similarly, the control signal CNTL can be used to set the voltage level of the second bias voltage 105b to the first bias voltage level V_{B1} or to the second bias voltage level V_{B2}, and to set the voltage level of the third bias voltage 105c to the first bias voltage level V_{B1} or to the second bias voltage level V_{B2}.

By controlling the voltage levels of the bias voltages to the first or second bias voltage levels V_{B1}, V_{B2}, the variable capacitor array 101 can exhibit a small variation in capacitance in the presence of an RF signal at the RF input RF_{IN}. Accordingly, the variable capacitor array 101 can exhibit high linearity in the presence of RF signals.

The control signal CNTL can control an overall capacitance of the variable capacitor array 101. For example, the size of the first, second, and third MOS capacitors cells 111a 111c can be weighted relative to one another, and an overall capacitance of the variable capacitor array 101 can be based on a sum of the capacitances of the array's variable capacitor cells.

In one embodiment, the variable capacitor array's variable capacitor cells are scaled by a factor of 2, and each of the variable capacitor cells includes k pairs of anti-series MOS capacitors connected in a cascade. For example, a second variable capacitor cell of the variable capacitor array can have a size that is about a factor of 2 relative to a first variable capacitor cell of the variable capacitor array. Additionally, an nth variable capacitor cell in the array can have a size that is about 2ⁿ⁻¹ that of the first variable capacitor cell, where n is an integer greater than or equal to 2. Although one possible variable capacitor array sizing scheme has been described, other configurations are possible.

When a variable capacitor array includes n variable capacitor cells that are scaled by a factor of 2 relative to one another and that include k pairs of anti-series MOS capacitors in a cascade, the bias voltage generation circuit 104 can control the array's first variable capacitor cell to a capacitance of C₁/2k or C₂/2k by biasing the first variable capacitor cell with the first bias voltage level V_{B1} or the second bias voltage level V_{B2}. Additionally, the bias voltage generation circuit 104 can control the array's second variable capacitor cell to a capacitance of 2¹*C₁/2k or 2¹*C₂/2k by biasing the second variable capacitor cell with the first bias voltage level V_{B1} or the second bias voltage level VB2. Furthermore, the bias voltage generation circuit 104 can control the array's nth variable capacitor cell to a capacitance of 2ⁿ⁻¹*C₁/2k or 2ⁿ⁻¹*C₂/2k by biasing the nth variable capacitor cell with the first bias voltage level V_{B1} or the second bias voltage level V_{B2}.

Configuring the bias voltage generation circuit 104 to control a bias voltage to one of two voltage levels can simplify a coding scheme associated with the control signal CNTL. For example, in such a configuration, the control signal CNTL can comprise a digital control signal, and individual bits of the digital control signal can be used to control the array's bias voltages to a particular bias voltage level. Although one possible coding scheme of the control signal CNTL has been described, other configurations are possible.

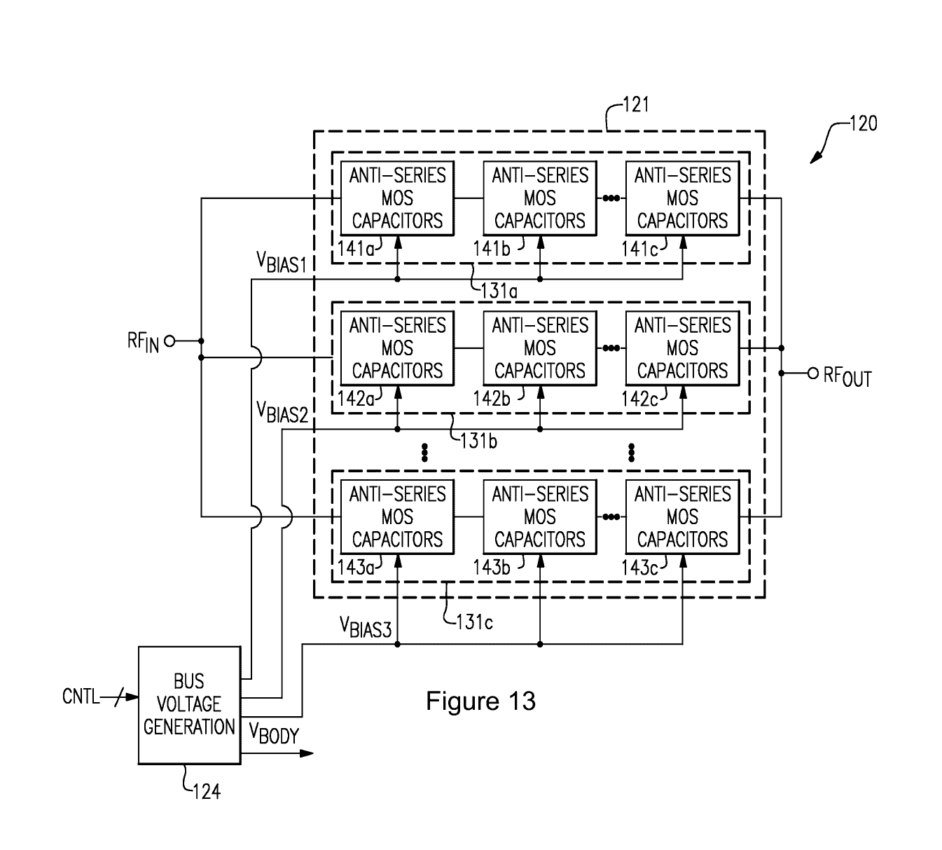

FIG. 13 is a schematic diagram of an IC 120 according to another embodiment. The IC 120 includes a variable capacitor array 121 and a bias voltage generation circuit 124. Although FIG. 13 illustrates a configuration in which the IC 120 includes one variable capacitor array, the IC 100 can be adapted to include additional variable capacitor arrays and/or other circuitry.

The variable capacitor array 121 includes a first variable capacitor cell 121a, a second variable capacitor cell 121b, and a third variable capacitor cell 121c, which have been electrically connected in parallel between an RF input RF_{IN} and an RF output RF_{OUT}. The first variable capacitor cell 121a includes a cascade of a first pair of anti-series MOS capacitors 141a, a second pair of anti-series MOS capacitors 141b, and a third pair of anti-series MOS capacitors 141c. The second variable capacitor cell 121b includes a cascade of a first pair of anti-series MOS capacitors 142a, a second pair of anti-series MOS capacitors 142b, and a third pair of anti-series MOS capacitors 142c. The third variable capacitor cell 121c includes a cascade of a first pair of anti-series MOS capacitors 143a, a second pair of anti-series MOS capacitors 143b, and a third pair of anti-series MOS capacitors 143c. Although the illustrated variable capacitor array 121 includes three variable capacitor cells, the variable capacitor array 121 can be adapted to include more or fewer variable capacitor cells. Additionally, although the illustrated variable capacitor cells each include a cascade of three pairs of anti-series MOS capacitors, the variable capacitor cells can include more or fewer pairs of anti-series MOS capacitors.

The bias voltage generation circuit 124 receives the control signal CNTL, and generates a first bias voltage V_{BIAS1} for the first variable capacitor cell 131a, a second bias voltage V_{BIAS2} for the second variable capacitor cell 131b, and a third bias voltage V_{BIAS3} for the third variable capacitor cell 131c. In certain configurations, the bias voltage generation circuit 124 can also be used to generate a body bias voltage V_{BODY}, which can be used to control the body voltages of MOS capacitors of the variable capacitor array 121.

Additional details of the integrated circuit 120 can be similar to those described earlier.

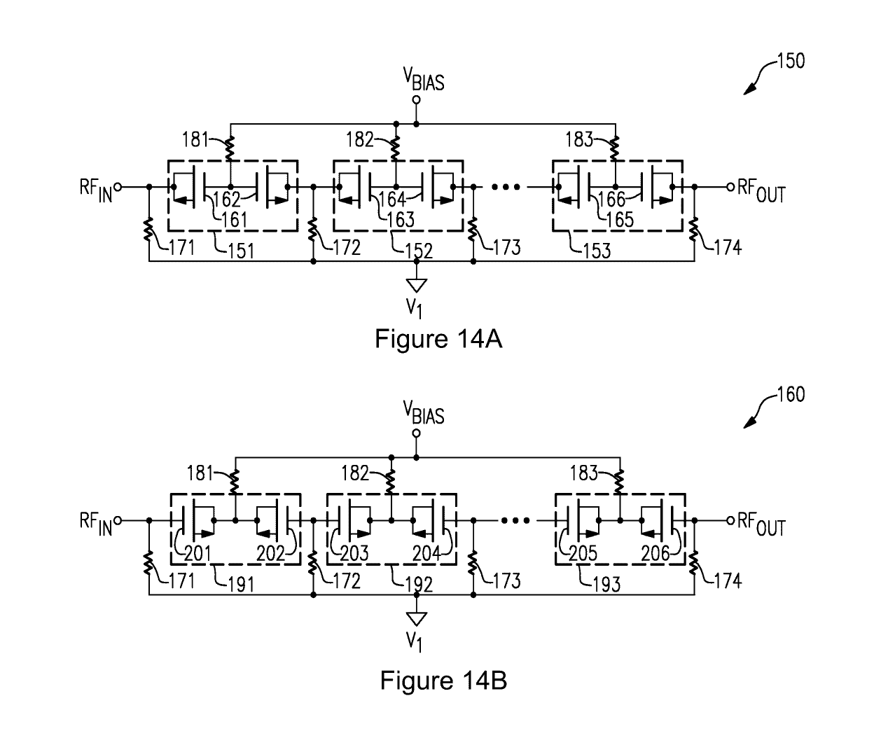

FIG. 14A is a schematic diagram of a variable capacitor cell 150 according to one embodiment. The variable capacitor cell 150 includes a first pair of anti-series MOS capacitors 151, a second pair of anti-series MOS capacitors 152, a third pair of anti-series MOS capacitors 153, a first DC biasing resistor 171, a second DC biasing resistor 172, a third DC biasing resistor 173, a fourth DC biasing resistor 174, a first control biasing resistor 181, a second control biasing resistor 182, and a third control biasing resistor 183.

Although the variable capacitor cell 150 is illustrated as including three pairs of anti-series MOS capacitors, the teachings herein are applicable to configurations including more or fewer pairs of anti-series MOS capacitors. For example, in one embodiment, a variable capacitor cell includes a cascade of between 2 and 18 pairs of anti-series MOS capacitors.

In the illustrated configuration, each of the pairs of anti-series MOS capacitors 151-153 includes two MOS capacitors electrically connected in anti-series or inverse series. For example, the first pair of anti-series MOS capacitors 151 includes a first MOS capacitor 161 and a second MOS capacitor 162. The first and second MOS capacitors 161, 162 have anodes associated with transistor gates and cathodes associated with transistor source and drain regions. As shown in FIG. 14A, the anode of the first MOS capacitor 161 is electrically connected to the anode of the second MOS capacitor 162. Additionally, the second pair of anti-series MOS capacitors 152 includes a third MOS capacitor 163 and a fourth MOS capacitor 164, and the anode of the third MOS capacitor 163 is electrically connected to the anode of the fourth MOS capacitor 164. Furthermore, the third pair of anti-series MOS capacitors 153 includes fifth MOS capacitor 165 and a sixth MOS capacitor 166, and the anode of the fifth MOS capacitor 165 is electrically connected to the anode of the sixth MOS capacitor 166.

As shown in FIG. 14A, the first to third pairs of anti-series MOS capacitors 151-153 are arranged in a cascade between the RF input RF_{IN} and the RF output RF_{OUT}. For example, the cathode of the first MOS capacitor 161 is electrically connected to the RF input RF_{IN}, and the cathode of the second MOS capacitor 162 is electrically connected to the cathode of the third MOS capacitor 163. Additionally, the cathode of the fourth MOS capacitor 164 is electrically connected to the cathode of the fifth MOS capacitor 165, and a cathode of the sixth MOS capacitor 166 is electrically connected to the RF output RF_{OUT}.

Arranging two or more pairs of anti-series MOS capacitors in a cascade can increase a voltage handling capability of a variable capacitor cell relative to a configuration including a single pair of anti-series MOS capacitors. For example, arranging two or more pairs of anti-series MOS capacitors in a cascade can increase a voltage handling and/or power handling capability of the variable capacitor cell by distributing RF signal voltage across multiple MOS capacitors.

Accordingly, cascading several pairs of anti-series MOS capacitors can achieve high voltage operation of a variable capacitor cell.

Additionally, the illustrated variable capacitor cell 150 includes pairs of MOS capacitors that are electrically connected in anti-series, which can decrease capacitance variation in the presence of RF signals. For example, when the first and second variable capacitors are each biased with a particular bias voltage, the variable capacitors' capacitance may change when an RF input signal is received on the RF input RF_{IN}. However, a capacitance variation ΔC between MOS capacitors in a given pair can have about equal magnitude, but opposite polarity.

For instance, in the presence of an RF input signal that generates a capacitance variation having a magnitude ΔC, a first MOS capacitor of a pair of anti-series MOS capacitors may have a capacitance C_{V}+ΔC, while the second MOS capacitor may have a capacitance C_{V}−ΔC. Thus, the total capacitance of the anti-series combination of the first and second MOS capacitors 121, 122 can be about equal to ½C_{V}−½ΔC²/C_{V}. Since ½ΔC² is typically much smaller than ΔC, the anti-series MOS capacitors can exhibit small capacitance variation when RF signals propagate through the variable capacitor cell.

Accordingly, the illustrated variable capacitor cell 150 can provide reduced capacitance variation in the presence of RF signals.

In the illustrated configuration, the first to fourth DC biasing resistors 171-174 have been used to bias the cathodes of the MOS capacitors 161-166 with the first voltage V₁, which can be a ground, power low supply, or other reference voltage in certain implementations. Additionally, the first to third control biasing resistors 181-183 are used to bias the anodes of the MOS capacitors 161-166 with the bias voltage V_{BIAS}.

In one embodiment, the DC biasing resistors 171-174 have a resistance selected in the range of 10 kΩ to 10,000 kΩ, and the control biasing resistors 181-183 have a resistance selected in the range of 10 kΩ to 10,000 kΩ. Although one example of resistance values have been provided, other configurations are possible. For example, choosing relatively low resistance values for the biasing resistors can increase control over DC biasing conditions, but can also undesirably increase signal loss and/or degrade linearity since the resistors operate in shunt to an RF signal propagating through the variable capacitor cell. Accordingly, resistance values can vary depending on application, fabrication process, and/or desired performance specifications.

The bias voltages across the MOS capacitors 161-166 can be based on a voltage difference between the bias voltage V_{BIAS} and the first voltage V₁. Additionally, a bias voltage generation circuit, such as the bias voltage generation circuit 64 of FIG. 10, can be used to control a voltage level of the bias voltage V_{BIAS} to control the variable capacitor cell's capacitance between the RF input RF_{IN} and the RF output RF_{OUT}.

In certain configurations, the bias voltage generation circuit can control the bias voltage V_{BIAS} to a voltage level selected from a discrete number of two or more bias voltage levels associated with high linearity. Thus, rather than biasing the MOS capacitors at a bias voltage level selected from a continuous tuning voltage range, the bias voltage generation circuit generates the MOS capacitors' bias voltages by selecting a particular cell's bias voltage level from a discrete set of bias voltage levels associated with high linearity. In one embodiment, the bias voltage generation circuit biases a particular MOS capacitor either at a first bias voltage level associated with an accumulation mode of the MOS capacitor or at a second bias voltage level associated an inversion mode of the MOS capacitor.

Biasing the MOS capacitors 161-166 in this manner can improve linearity relative to a configuration in which the MOS capacitors 161-166 are biased at a bias voltage level selected from a continuous tuning voltage range. For example, a MOS capacitor can exhibit a change in capacitance in response to changes in an applied RF signal, and a magnitude of the capacitance change can vary with the MOS capacitor's bias voltage level.

Accordingly, the illustrated variable capacitor cell 150 can provide high linearity between the RF input RF_{IN} and the RF output RF_{OUT}.

FIG. 14B is a circuit diagram of a variable capacitor cell 160 according to one embodiment. The variable capacitor cell 160 includes a first pair of anti-series MOS capacitors 191, a second pair of anti-series MOS capacitors 192, a third pair of anti-series MOS capacitors 193, a first DC biasing resistor 171, a second DC biasing resistor 172, a third DC biasing resistor 173, a fourth DC biasing resistor 174, a first control biasing resistor 181, a second control biasing resistor 182, and a third control biasing resistor 183. Although the variable capacitor cell 160 is illustrated as including three pairs of anti-series MOS capacitors, the teachings herein are applicable to configurations including more or fewer pairs of anti-series MOS capacitors.

The variable capacitor cell 160 of FIG. 14B is similar to the variable capacitor cell 150 of FIG. 14A, except that the variable capacitor cell 160 illustrates a different anti-series configuration of the pairs of anti-series MOS capacitors 191-193.

In particular, in contrast to the variable capacitor cell 150 of FIG. 14A in which the anodes of the MOS capacitors of a given pair are electrically connected to one another, the variable capacitor cell 160 of FIG. 14B illustrates a configuration in which the cathodes of a given pair of MOS capacitors are electrically connected to one another. For example, the first pair of MOS capacitors 191 includes a first MOS capacitor 201 and a second MOS capacitor 202, and the cathodes of the first and second MOS capacitors 201, 202 are electrically connected to one another. Similarly, the second pair of MOS capacitors 192 includes a third MOS capacitor 203 and a fourth MOS capacitor 204, and the cathodes of the third and fourth MOS capacitors 203, 204 are electrically connected to one another. Likewise, the third pair of MOS capacitors 193 includes a fifth MOS capacitor 205 and a sixth MOS capacitor 206, and the cathodes of the fifth and sixth MOS capacitors 205, 206 are electrically connected to one another.

As shown in FIG. 14B, the pairs of anti-series MOS capacitors 191-193 are electrically connected in a cascade between the RF input RF_{IN} and the RF output RF_{OUT}. For example, the anode of the first MOS capacitor 201 is electrically connected to the RF input RF_{IN}, and the anode of the second MOS capacitor 202 is electrically connected to the anode of the third MOS capacitor 203. Additionally, the anode of the fourth MOS capacitor 204 is electrically connected to the anode of the fifth MOS capacitor 205, and an anode of the sixth MOS capacitor 206 is electrically connected to the RF output RF_{OUT}.

In the illustrated configuration, the first to fourth DC biasing resistors 171 174 are used to bias the anodes of the MOS capacitors 201-206 with the first voltage V₁, which can be a ground, power low supply, or other reference voltage in certain implementations. Additionally, the first to third control biasing resistors 181-183 are used to bias the cathodes of the MOS capacitors 201-206 with the bias voltage V_{BIAS}.

In certain configurations, the variable capacitor cell 150 of FIG. 14A can be more robust against damage from electrostatic discharge (ESD) events relative to the variable capacitor cell 160 of FIG. 14B.

For example, the RF input RF_{IN} and RF output RF_{OUT} of a variable capacitor cell may be electrically connected to input and output pins of an IC on which the variable capacitor cell is fabricated. Since a MOS capacitor's source and drain regions typically can withstand a greater voltage relative to the MOS capacitor's gate region when fabricated using certain manufacturing processes, the variable capacitor cell 150 of FIG. 14A may exhibit a greater robustness to ESD events or other overvoltage conditions relative to the variable capacitor cell 160 of FIG. 14B.

Additional details of the variable capacitor cell 160 can be similar to those described earlier.

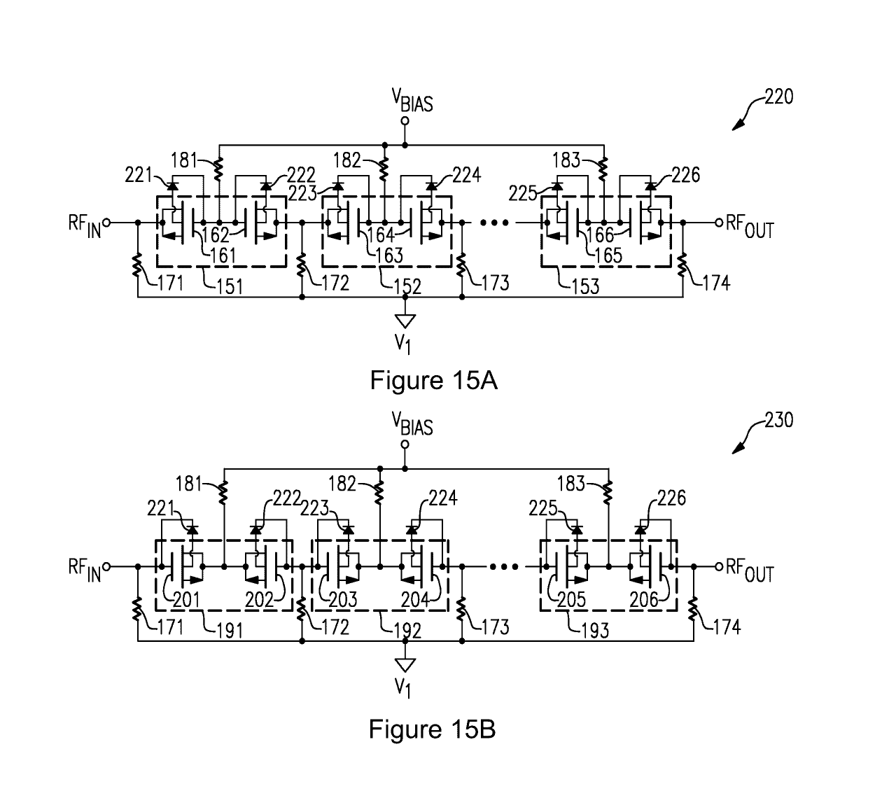

FIG. 15A is a variable capacitor cell 220 according to another embodiment. The variable capacitor cell 220 of FIG. 15A is similar to the variable capacitor cell 150 of FIG. 14A, except that the variable capacitor cell 220 of FIG. 15A further includes a first diode 221, a second diode 222, a third diode 223, a fourth diode 224, a fifth diode 225, and a sixth diode 226.

As shown in FIG. 15A, the diodes 221-226 are electrically connected between the body and gate of the MOS capacitors 161-166, respectively. In particular, the anodes of the diodes 221-226 are electrically connected to the bodies of the MOS capacitors 161-166, respectively, and the cathodes of the diodes 221-226 are electrically connected to the gates of the MOS capacitors 161-166, respectively. The diodes 221-226 can be included in a variety of manufacturing processes, such as silicon-on-insulator (SOI) processes. In certain configurations, the diodes 221-226 are implemented as p n junction diodes. For example, an n-type MOS capacitor can include a p-type body region, and an n-type active region can be included in the p-type body region and electrically connected to the gate via metallization to provide a forward p-n junction diode from body to gate.

Including the diodes 221-226 can enhance the performance in the presence of RF signaling conditions, including, for example, enhanced performance in the presence of voltage changes to an RF signal over a signal cycle. For example, the diodes 221-226 can increase voltage headroom of the MOS capacitors 161-166 relative to a configuration in which the diodes 221-226 are omitted. Additionally, the diodes 221-226 can aid in better distributing an RF signal voltage across the MOS capacitors 161-166, thereby preventing large voltage build-up across a particular MOS capacitor in the cascade. Thus, the illustrated configuration can exhibit greater signal handling and/or power handling capability relative to a configuration that omits the diodes 221-226.

Additional details of the variable capacitor cell 220 can be similar to those described earlier.

FIG. 15B is a circuit diagram of a variable capacitor cell 230 according to another embodiment. The variable capacitor cell 230 of FIG. 15B is similar to the variable capacitor cell 160 of FIG. 14B, except that the variable capacitor cell 230 of FIG. 15B further includes the first to sixth diodes 221-226.

As shown in FIG. 15B, the anodes of the diodes 221-226 are electrically connected to the bodies of the MOS capacitors 201-206, respectively, and the cathodes of the diodes 221-226 are electrically connected to the gates of the MOS capacitors 201-206, respectively. Including the diodes 221-226 can improve RF signal voltage distribution and/or increase voltage headroom of the MOS capacitors 201-206.

Additional details of the variable capacitor cell 230 can be similar to those described earlier.

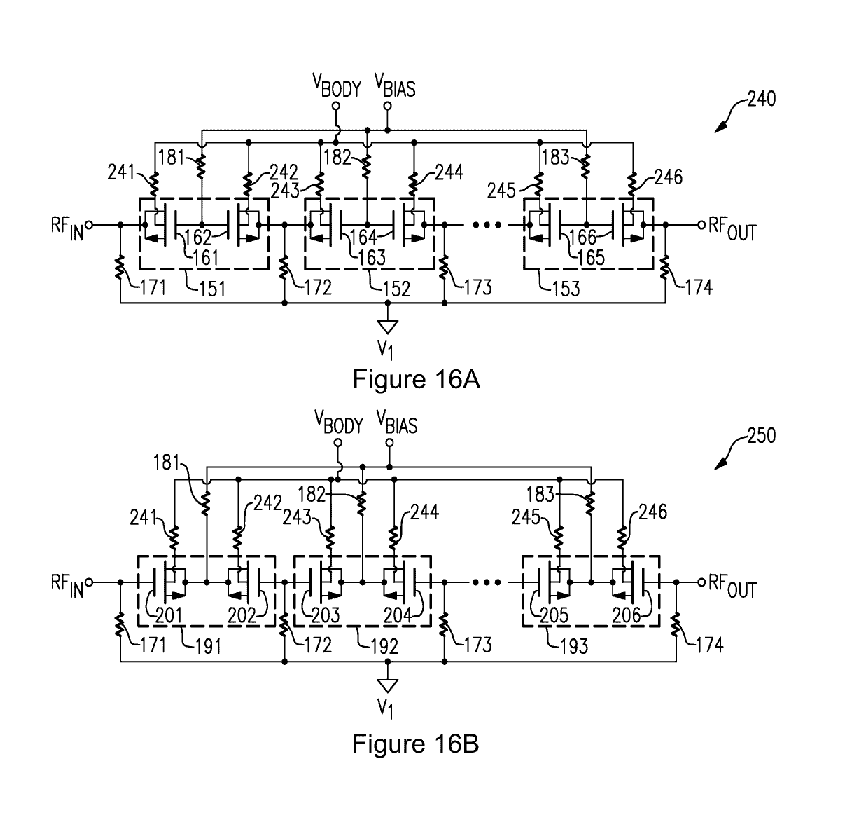

FIG. 16A is a circuit diagram of a variable capacitor cell 240 according to another embodiment. The variable capacitor cell 240 of FIG. 16A is similar to the variable capacitor cell 150 of FIG. 14A, except that the variable capacitor cell 240 of FIG. 16A further includes a first body biasing resistor 241, a second body biasing resistor 242, a third body biasing resistor 243, a fourth body biasing resistor 244, a fifth body biasing resistor 245, and a sixth body biasing resistor 246.

The body biasing resistor 241-246 are used to bias the bodies of the MOS capacitors 161-166 with a body bias voltage V_{BODY}. Including the body biasing resistors 241-246 can aid in increasing the voltage headroom of the MOS capacitors 161-166 in the presence of RF voltage swing. In certain configurations, the body bias voltage V_{BODY} is generated by a bias voltage generation circuit, such as the bias voltage generation circuit 124 of FIG. 13.

The body biasing resistors 241-246 can have any suitable resistance value. In one embodiment, the body biasing resistors 241-246 have a resistance selected in the range of 10 kΩ to 10,000 kΩ. Although one example of resistance values have been provided, other configurations are possible, such as resistance values selected for a particular application, fabrication process, and/or desired performance specifications.

Additional details of the variable capacitor cell 240 can be similar to those described earlier.

FIG. 16B is a circuit diagram of a variable capacitor cell 250 according to another embodiment. The variable capacitor cell 250 of FIG. 16B is similar to the variable capacitor cell 160 of FIG. 14B, except that the variable capacitor cell 250 of FIG. 16B further includes the first to sixth body biasing resistors 241 246.

As shown in FIG. 16B, the body biasing resistors 241 246 are electrically connected between the body bias voltage V_{BODY} and the bodies of the MOS capacitors 201-206, respectively. Including the body biasing resistors 241 246 can increase voltage headroom of the MOS capacitors 201 206 in the presence of amplitude change or swing of an RF signal.

Additional details of the variable capacitor cell 250 can be similar to those described earlier.

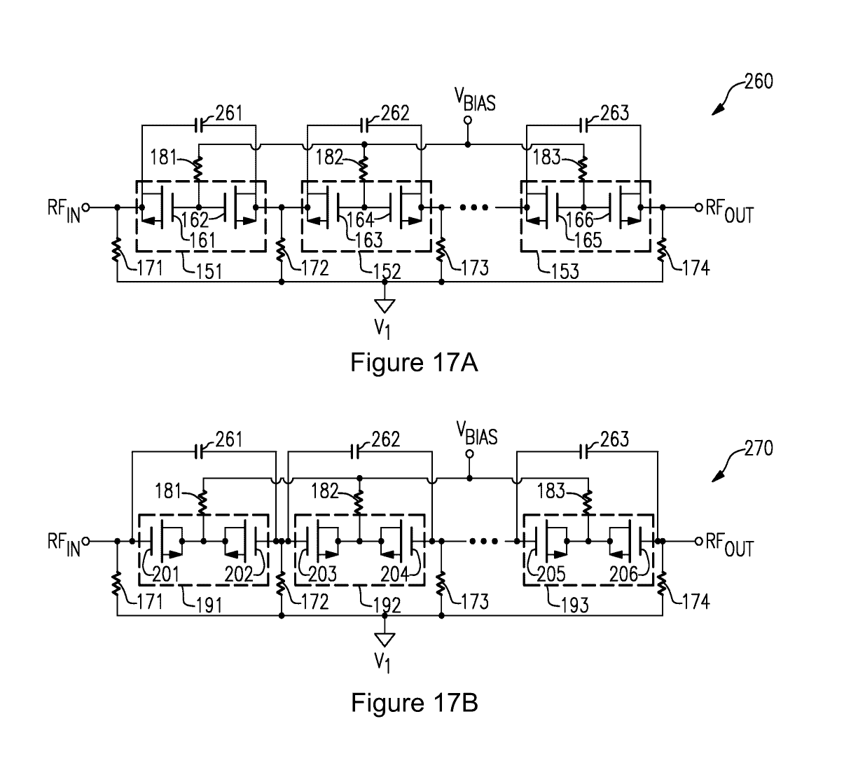

FIG. 17A is a circuit diagram of a variable capacitor cell 260 according to another embodiment. The variable capacitor cell 260 of FIG. 17A is similar to the variable capacitor cell 150 of FIG. 17A, except that the variable capacitor cell 260 of FIG. 17A further includes a first signal swing compensation capacitor 261, a second signal swing compensation capacitor 262, and a third signal swing compensation capacitor 263.

As shown in FIG. 17A, the first signal swing compensation capacitor 261 is electrically connected in parallel with the first pair of anti-series MOS capacitors 151. For example, the first signal swing compensation capacitor 261 includes a first end electrically connected to the cathode of the first MOS capacitor 161 and a second end electrically connected to the cathode of the second MOS capacitor 162. Similarly, the second signal swing compensation capacitor 262 is electrically connected in parallel with the second pair of anti-series MOS capacitors 152, and the third signal swing compensation capacitor 263 is electrically connected in parallel with the third pair of anti-series MOS capacitors 153.

The signal swing compensation capacitors 261-263 can be used to balance or compensate for differences in voltage, current, and/or phase between pairs of anti-series MOS capacitors. Absent compensation, variation in voltage, current, and/or phase between MOS capacitors may degrade the variable capacitor cell's linearity.

In certain configurations, the capacitance values of the signal swing compensation capacitors 261-263 can be individually selected to improve voltage, current, and/or phase balancing between MOS capacitors 161-166. For example, even when the MOS capacitors 161-166 are implemented with the same size and/or geometry, the capacitance values of the signal switch compensation capacitors 261-263 can be individually selected to provide improve compensation in the presence of RF signaling conditions. In one embodiment, the first signal swing compensation capacitor 261 has a capacitance value that is greater than that of the second signal swing compensation capacitor 262, and the second signal swing compensation capacitor 262 has a capacitance value that is greater than that of the third signal swing compensation capacitor 263. Sizing the signal swing compensation capacitors in this manner may provide enhanced balancing in certain configurations, such as configurations in which large amplitude RF signals are received at the RF input RF_{IN}.

Additional details of the variable capacitor cell 260 can be similar to those described earlier.

FIG. 17B is a circuit diagram of a variable capacitor cell 270 according to another embodiment. The variable capacitor cell 270 of FIG. 17B is similar to the variable capacitor cell 160 of FIG. 17B, except that the variable capacitor cell 270 of FIG. 17B further includes the signal swing compensation capacitors 261-263.

As shown in FIG. 17B, the first signal swing compensation capacitor 261 is electrically connected in parallel with the first pair of anti-series MOS capacitors 191. For example, the first signal swing compensation capacitor 261 includes a first end electrically connected to the anode of the first MOS capacitor 201 and a second end electrically connected to the anode of the second MOS capacitor 202. Similarly, the second signal swing compensation capacitor 262 is electrically connected in parallel with the second pair of anti-series MOS capacitors 192, and the third signal swing compensation capacitor 263 is electrically connected in parallel with the third pair of anti-series MOS capacitors 193.

The signal swing compensation capacitors 261-263 can be included to balance differences in voltage, current, and/or phase between adjacent MOS capacitors, thereby improving linearity of the variable capacitor cell.

Additional details of the variable capacitor cell 270 can be similar to those described earlier.

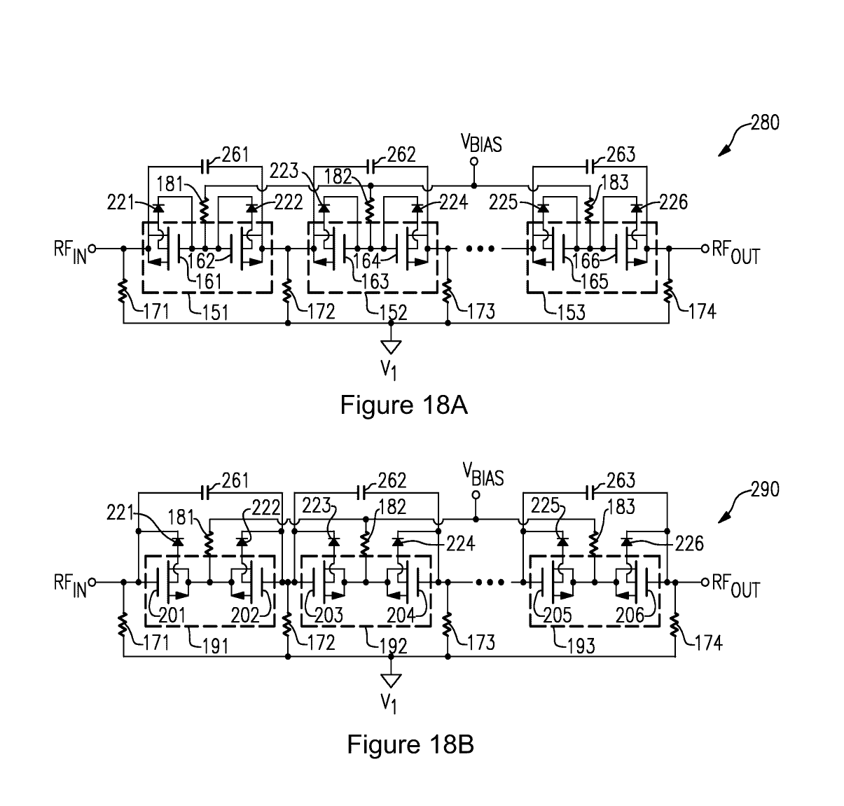

FIG. 18A is a circuit diagram of a variable capacitor cell 280 according to another embodiment. The variable capacitor cell 280 of FIG. 18A is similar to the variable capacitor cell 150 of FIG. 14A, except that the variable capacitor cell 280 of FIG. 18A further includes the diodes 221-226 and the signal swing compensation capacitors 261-263.

Additional details of the variable capacitor cell 280 can be similar to those described earlier.

FIG. 18B is a circuit diagram of a variable capacitor cell 290 according to another embodiment. The variable capacitor cell 290 of FIG. 18B is similar to the variable capacitor cell 160 of FIG. 14B, except that the variable capacitor cell 290 of FIG. 18B further includes the diodes 221-226 and the signal swing compensation capacitors 261-263.

Additional details of the variable capacitor cell 290 can be similar to those described earlier.

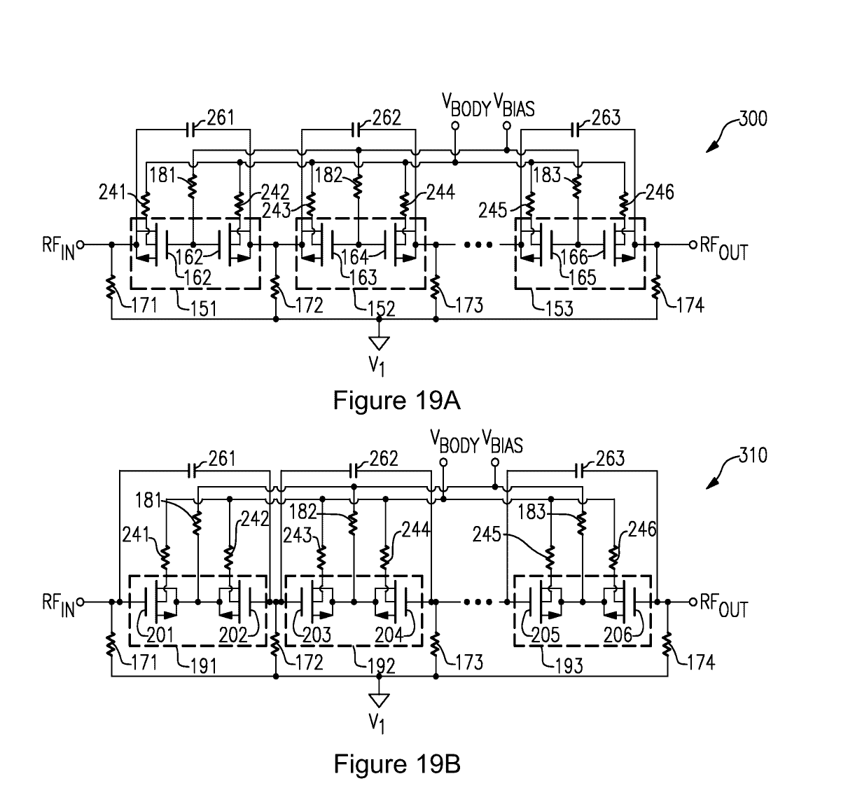

FIG. 19A is a circuit diagram of a variable capacitor cell 300 according to another embodiment. The variable capacitor cell 300 of FIG. 19A is similar to the variable capacitor cell 150 of FIG. 14A, except that the variable capacitor cell 300 of FIG. 19A further includes the body biasing resistors 241-246 and the signal swing compensation capacitors 261-263.

Additional details of the variable capacitor cell 300 can be similar to those described earlier.

FIG. 19B is a circuit diagram of a variable capacitor cell 310 according to another embodiment. The variable capacitor cell 310 of FIG. 19B is similar to the variable capacitor cell 160 of FIG. 14B, except that the variable capacitor cell 310 of FIG. 19B further includes the body biasing resistors 241-246 and the signal swing compensation capacitors 261-263.

Additional details of the variable capacitor cell 310 can be similar to those described earlier.

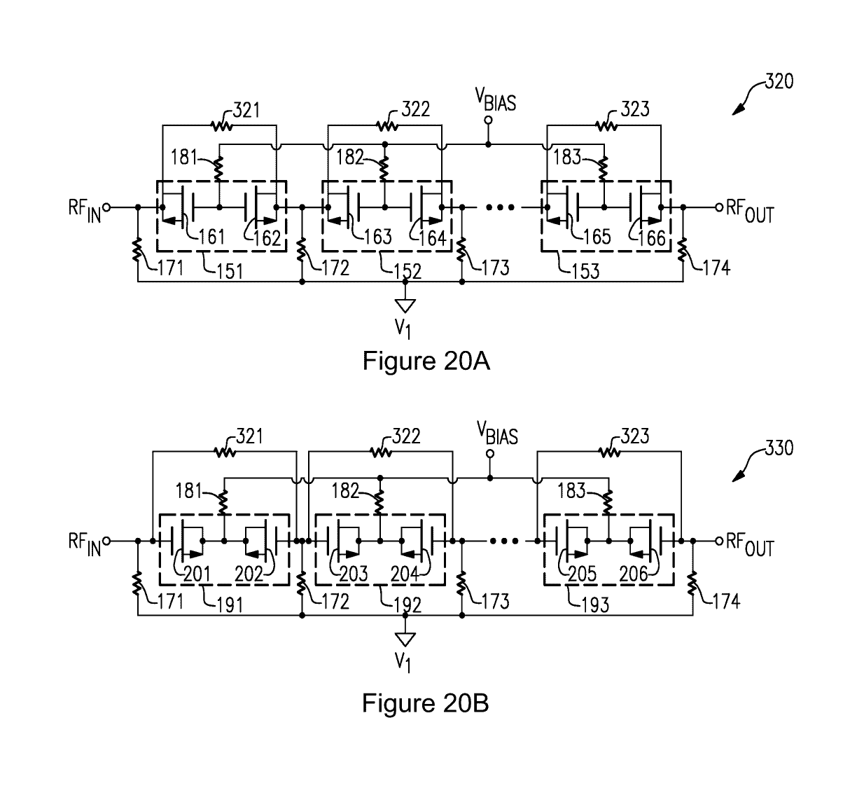

FIG. 20A is a circuit diagram of a variable capacitor cell 320 according to another embodiment. The variable capacitor cell 320 of FIG. 20A is similar to the variable capacitor cell 150 of FIG. 14A, except that the variable capacitor cell 320 of FIG. 20A further includes a first drift protection resistor 321, a second drift protection resistor 322, and a third drift protection resistor 323.

As shown in FIG. 20A, the first drift protection resistor 321 is electrically connected in parallel with the first pair of anti-series MOS capacitors 151. For example, the first drift protection resistor 321 includes a first end electrically connected to the cathode of the first MOS capacitor 161 and a second end electrically connected to the cathode of the second MOS capacitor 162. Similarly, the second drift protection resistor 322 is electrically connected in parallel with the second pair of anti-series MOS capacitors 152, and the third drift protection resistor 323 is electrically connected in parallel with the third pair of anti-series MOS capacitors 153.

The drift protection resistor 321-323 can be used to balance DC operating points across the MOS capacitors 161-166, thereby enhancing performance in the presence of RF amplitude variation or swing. As described earlier, a capacitance provided by a MOS capacitor changes with a voltage difference across the MOS capacitor's anode and cathode. Accordingly, balancing the DC operating point across the MOS capacitors 161-166 can help prevent the capacitances values of the MOS capacitors 161-166 from drifting and becoming unstable in the presence of RF signaling conditions.

In one embodiment, the drift protection resistors 321-323 have a resistance selected in the range of 5 kΩ to 1,000 kΩ. Although one example of resistance values have been provided, other configurations are possible. For example, choosing relatively low resistance values for the drift protection resistors can reduce capacitance value drift due to RF signal swing, but can also impact signaling performance since the resistors are electrically in series between the RF input RF_{IN} and the RF output RF_{OUT}. Accordingly, resistance values can vary depending on application, fabrication process, and/or desired performance specifications.

Additional details of the variable capacitor cell 320 can be similar to those described earlier.

FIG. 20B is a circuit diagram of a variable capacitor cell 330 according to another embodiment. The variable capacitor cell 330 of FIG. 20B is similar to the variable capacitor cell 160 of FIG. 14B, except that the variable capacitor cell 330 of FIG. 20B further includes the drift protection resistors 321-323.

As shown in FIG. 20B, the first drift protection resistor 321 is electrically connected in parallel with the first pair of anti-series MOS capacitors 191. For example, the first drift protection resistor 321 includes a first end electrically connected to the anode of the first MOS capacitor 201 and a second end electrically connected to the anode of the second MOS capacitor 202. Similarly, the second drift protection resistor 322 is electrically connected in parallel with the second pair of anti-series MOS capacitors 192, and the third drift protection resistor 323 is electrically connected in parallel with the third pair of anti-series MOS capacitors 193.

The drift protection resistors 321-323 can be included to prevent the capacitances values of the MOS capacitors 201-206 from drifting and becoming unstable in the presence of RF signaling conditions.

Additional details of the variable capacitor cell 330 can be similar to those described earlier.

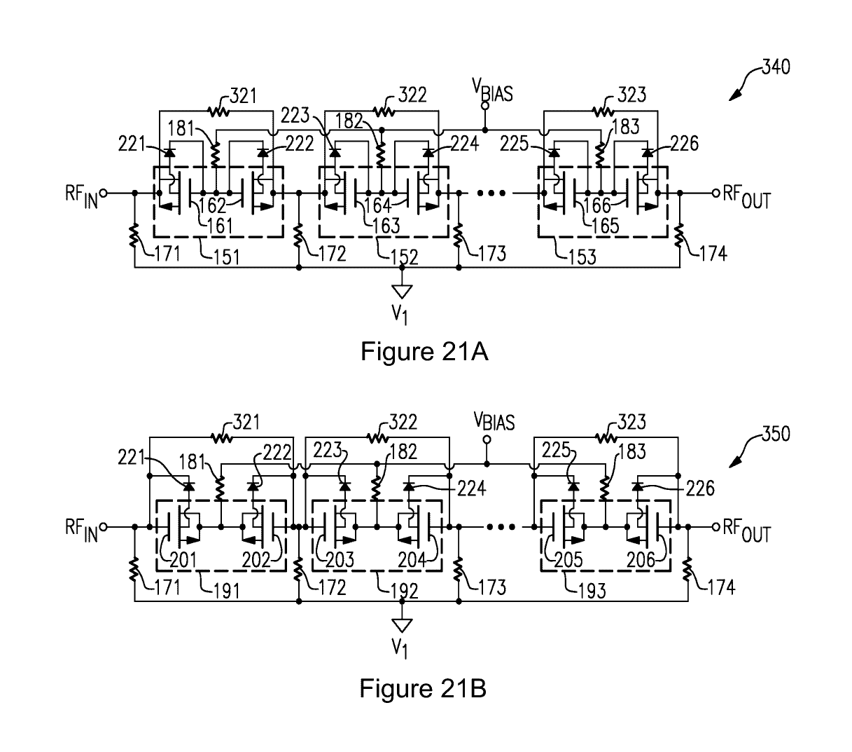

FIG. 21A is a circuit diagram of a variable capacitor cell 340 according to another embodiment. The variable capacitor cell 340 of FIG. 21A is similar to the variable capacitor cell 150 of FIG. 14A, except that the variable capacitor cell 340 of FIG. 21A further includes the diodes 221-226 and the drift protection resistors 321-323.

Additional details of the variable capacitor cell 340 can be similar to those described earlier.

FIG. 21B is a circuit diagram of a variable capacitor cell 350 according to another embodiment. The variable capacitor cell 350 of FIG. 21B is similar to the variable capacitor cell 160 of FIG. 14B, except that the variable capacitor cell 350 of FIG. 21B further includes the diodes 221-226 and the drift protection resistors 321-323.

Additional details of the variable capacitor cell 350 can be similar to those described earlier.

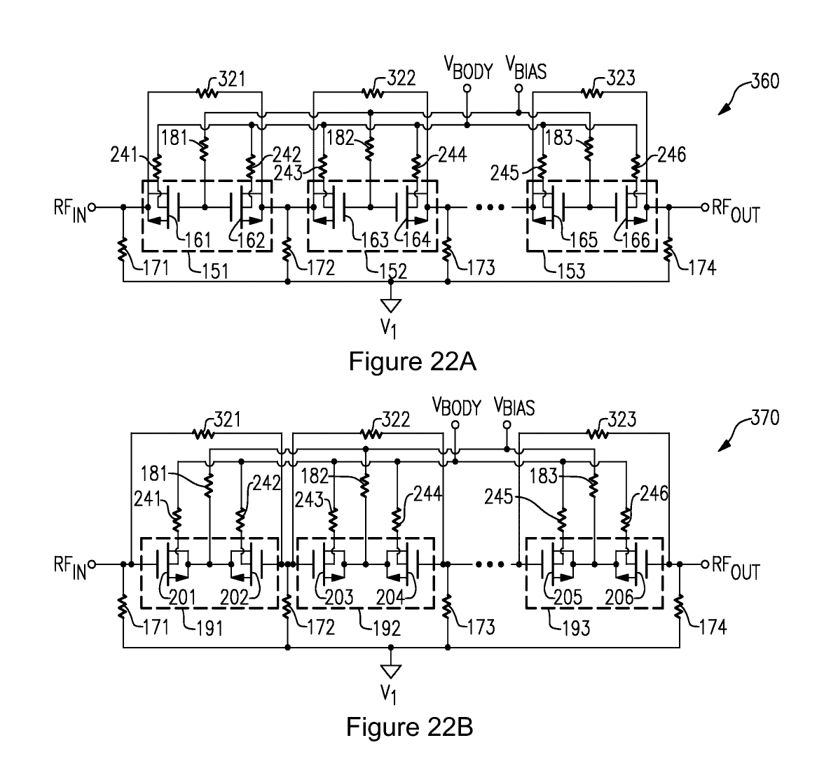

FIG. 22A is a circuit diagram of a variable capacitor cell 360 according to another embodiment. The variable capacitor cell 360 of FIG. 22A is similar to the variable capacitor cell 150 of FIG. 14A, except that the variable capacitor cell 360 of FIG. 22A further includes the body biasing resistors 241-246 and the drift protection resistors 321-323.

Additional details of the variable capacitor cell 360 can be similar to those described earlier.

FIG. 22B is a circuit diagram of a variable capacitor cell 370 according to another embodiment. The variable capacitor cell 370 of FIG. 22B is similar to the variable capacitor cell 160 of FIG. 14B, except that the variable capacitor cell 370 of FIG. 22B further includes the body biasing resistors 241-246 and the drift protection resistors 321-323.

Additional details of the variable capacitor cell 370 can be similar to those described earlier.

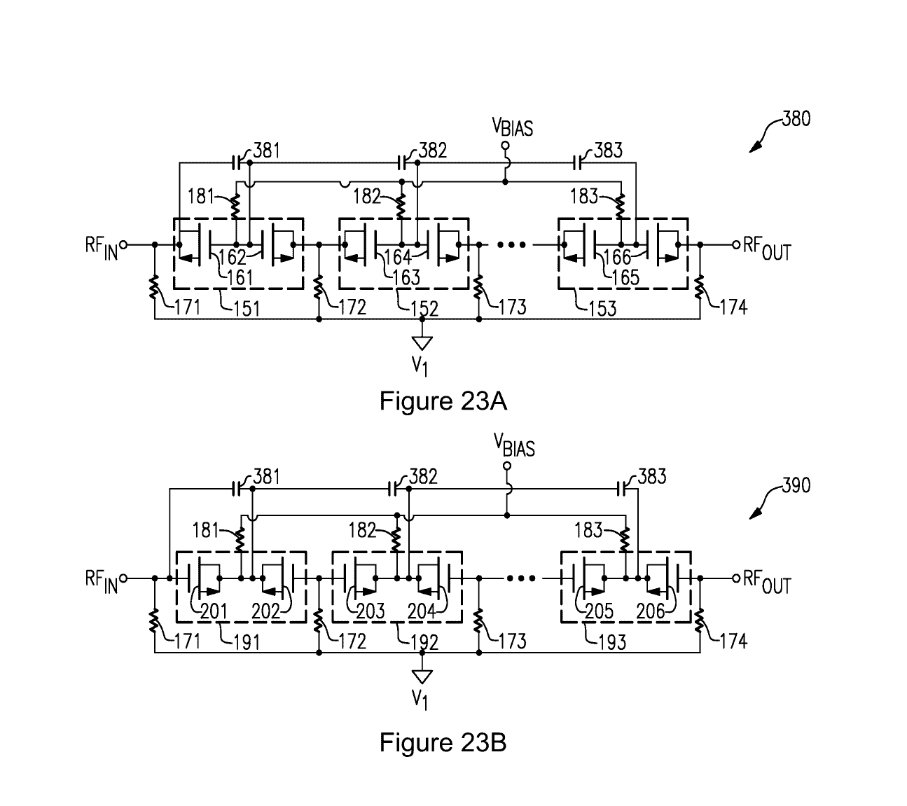

FIG. 23A is a circuit diagram of a variable capacitor cell 380 according to another embodiment. The variable capacitor cell 380 of FIG. 23A is similar to the variable capacitor cell 150 of FIG. 14A, except that the variable capacitor cell 380 of FIG. 23A further includes a first feed forward capacitor 381, a second feed-forward capacitor 382, and a third feed forward capacitor 383.

As shown in FIG. 23A, the first feed forward capacitor 381 is electrically connected between the RF input RF_{IN} and an intermediate node of the first pair of anti-series MOS capacitors 151. For example, the first feed forward capacitor 381 is electrically connected between the RF input RF_{IN} and the anodes of the first and second MOS capacitors 161, 162. Additionally, the second feed-forward capacitor 382 is electrically connected between the intermediate node of the first pair of anti-series MOS capacitors 151 and an intermediate node of the second pair of anti-series MOS capacitors 152. For example, the second feed forward capacitor 382 includes a first end electrically connected to the anodes of the first and second MOS capacitors 161, 162 and a second end electrically connected to anodes of the third and fourth MOS capacitors 163, 164. Furthermore, the third feed forward capacitor 383 is electrically connected between the intermediate node of the second pair of anti-series MOS capacitors 152 and an intermediate node of the third pair of anti-series MOS capacitors 153. For example, the third feed forward capacitor 383 includes a first end electrically connected to the anodes of the third and fourth MOS capacitors 163, 164, and a second end electrically connected to anodes of the fifth and sixth MOS capacitors 165, 166.

The feed forward capacitors 381-383 can be used to balance or compensate for differences in voltage, current, and/or phase between MOS capacitors. For example, the feed forward capacitors 381-383 can be used to balance an RF voltage drop across the MOS capacitors 161-166, thereby improving the linearity of the variable capacitor cell.

In certain configurations, the feed forward capacitors 381-383 can be individually selected to improve voltage, current, and/or phase balancing between MOS capacitors 161-166. For example, even when the MOS capacitors 161-166 are implemented with the same size and/or geometry, the capacitance values of the feed forward capacitors 381-383 can be individually selected to provide improve compensation in the presence of RF signaling conditions. In one embodiment, the first feed forward capacitor 381 has a capacitance value that is greater than that of the second feed forward capacitor 382, and the second feed forward capacitor 382 has a capacitance value that is greater than that of the third feed forward capacitor 383. Sizing the feed forward capacitors in this manner may provide enhanced balancing in certain configurations, such as configurations in which large amplitude RF signals are received at the RF input RF_{IN}.

Additional details of the variable capacitor cell 380 can be similar to those described earlier.

FIG. 23B is a circuit diagram of a variable capacitor cell 390 according to another embodiment. The variable capacitor cell 390 of FIG. 23B is similar to the variable capacitor cell 160 of FIG. 14B, except that the variable capacitor cell 390 of FIG. 23B further includes the feed forward capacitors 381-383.

As shown in FIG. 23B, the first feed forward capacitor 381 is electrically connected between the RF input RF_{IN} and an intermediate node of the first pair of anti-series MOS capacitors 191. For example, the first feed forward capacitor 381 is electrically connected between the RF input RF_{IN} and the cathodes of the first and second MOS capacitors 201, 202. Additionally, the second feed-forward capacitor 382 is electrically connected between the intermediate node of the first pair of anti-series MOS capacitors 191 and an intermediate node of the second pair of anti-series MOS capacitors 192. For example, the second feed forward capacitor 382 includes a first end electrically connected to the cathodes of the first and second MOS capacitors 201, 202 and a second end electrically connected to cathodes of the third and fourth MOS capacitors 203, 204. Furthermore, the third feed forward capacitor 383 is electrically connected between the intermediate node of the second pair of anti-series MOS capacitors 192 and an intermediate node of the third pair of anti-series MOS capacitors 193. For example, the third feed forward capacitor 383 includes a first end electrically connected to the cathodes of the third and fourth MOS capacitors 203, 204, and a second end electrically connected to cathodes of the fifth and sixth MOS capacitors 205, 206.

The feed forward capacitors 381 383 can be included to balance differences in voltage, current, and/or phase between MOS capacitors, thereby improving linearity of the variable capacitor cell.

Additional details of the variable capacitor cell 390 can be similar to those described earlier.

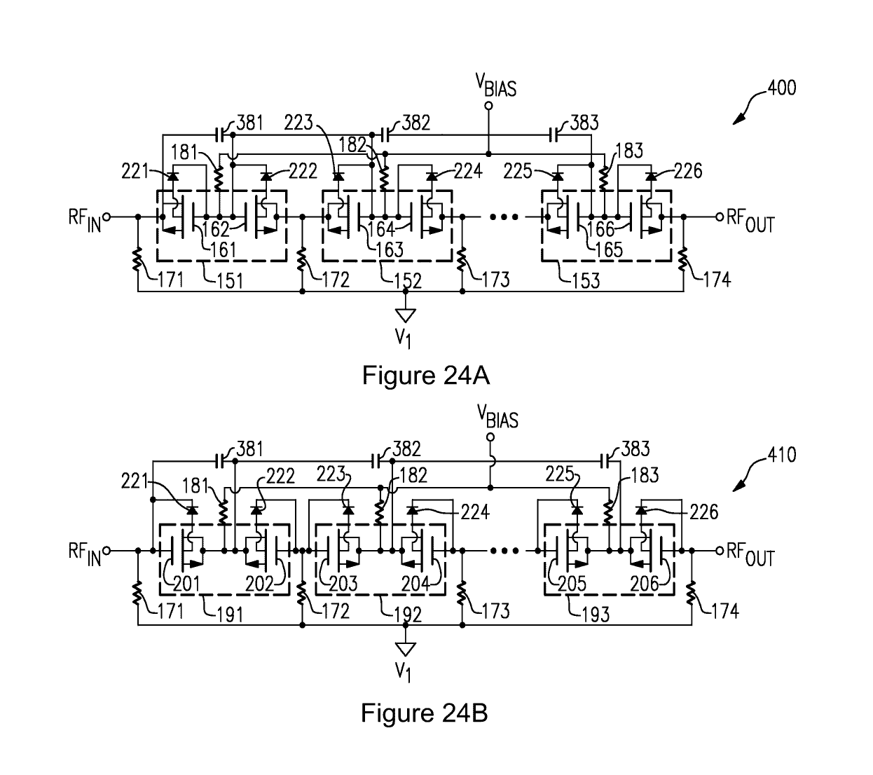

FIG. 24A is a circuit diagram of a variable capacitor cell 400 according to another embodiment. The variable capacitor cell 400 of FIG. 24A is similar to the variable capacitor cell 150 of FIG. 14A, except that the variable capacitor cell 400 of FIG. 24A further includes the diodes 221-226 and the feed forward capacitors 381-383.

Additional details of the variable capacitor cell 400 can be similar to those described earlier.

FIG. 24B is a circuit diagram of a variable capacitor cell 410 according to another embodiment. The variable capacitor cell 410 of FIG. 24B is similar to the variable capacitor cell 160 of FIG. 14B, except that the variable capacitor cell 410 of FIG. 24B further includes the diodes 221-226 and the feed forward capacitors 381-383.

Additional details of the variable capacitor cell 410 can be similar to those described earlier.

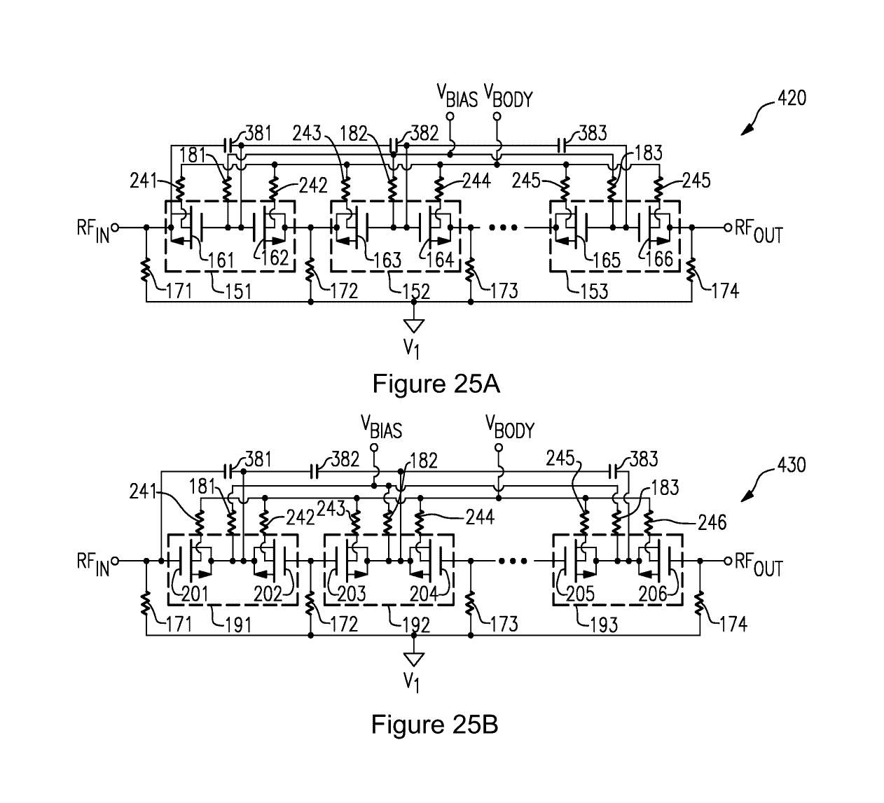

FIG. 25A is a circuit diagram of a variable capacitor cell 420 according to another embodiment. The variable capacitor cell 420 of FIG. 25A is similar to the variable capacitor cell 150 of FIG. 14A, except that the variable capacitor cell 420 of FIG. 25A further includes the body biasing resistors 241-246 and the feed forward capacitors 381-383.

Additional details of the variable capacitor cell 420 can be similar to those described earlier.

FIG. 25B is a circuit diagram of a variable capacitor cell 430 according to another embodiment. The variable capacitor cell 430 of FIG. 25B is similar to the variable capacitor cell 160 of FIG. 14B, except that the variable capacitor cell 430 of FIG. 25B further includes the body biasing resistors 241-246 and the feed forward capacitors 381-383.

Additional details of the variable capacitor cell 430 can be similar to those described earlier.

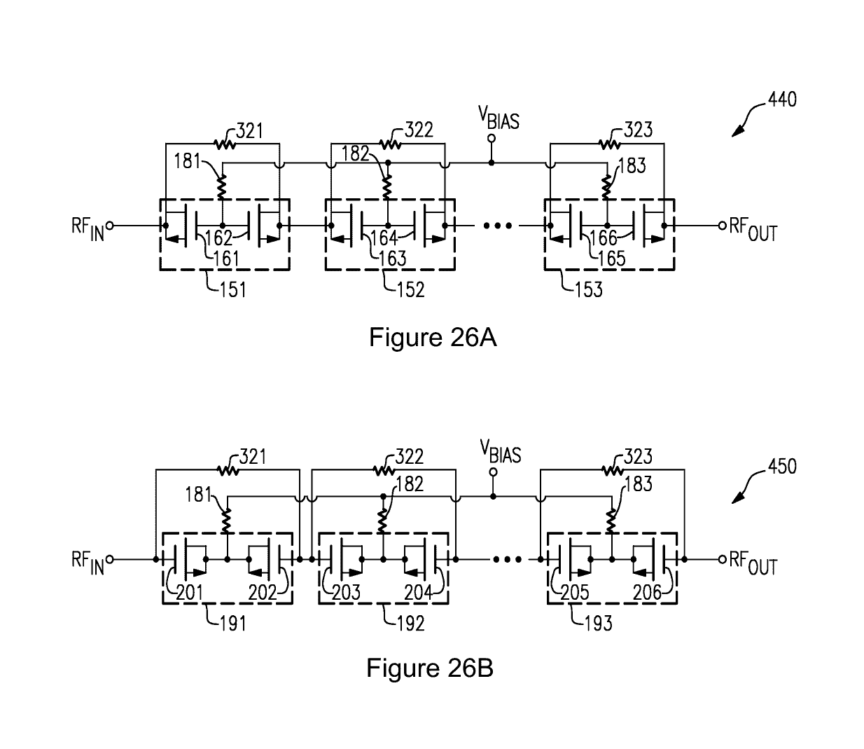

FIG. 26A is a circuit diagram of a variable capacitor cell 440 according to another embodiment. The variable capacitor cell 440 of FIG. 26A is similar to the variable capacitor cell 320 of FIG. 20A, except that the variable capacitor cell 440 of FIG. 26A omits the first to fourth DC biasing resistors 171-174.

As described earlier, the drift protection resistor 321-323 can be used to balance DC operating points across the MOS capacitors 161-166, thereby enhancing performance in the presence of RF amplitude variation or swing. In the illustrated configuration, the first to fourth DC biasing resistors 171-174 have been omitted in favor of controlling the DC bias voltage at the cathodes of the MOS capacitors 161-166 using the drift protection resistors 321-323. For example, in the illustrated configuration, the DC bias voltage at the cathodes of the MOS capacitors 161-166 can be controlled to a DC bias voltage of the RF input RF_{IN} and RF output RF_{OUT}. Additionally, one of the terminals RF_{IN} or RF_{OUT} may be grounded when used in a shunt configuration, thus eliminating the need of first to fourth DC biasing resistors 171-174.

Additional details of the variable capacitor cell 440 can be similar to those described earlier.

FIG. 26B is a circuit diagram of a variable capacitor cell 450 according to another embodiment. The variable capacitor cell 450 of FIG. 26B is similar to the variable capacitor cell 330 of FIG. 20B, except that the variable capacitor cell 450 of FIG. 26B omits the first to fourth DC biasing resistors 171-174.

As shown in FIG. 26B, the first to fourth DC biasing resistors 171-174 have been omitted in favor of controlling the DC bias voltage at the anodes of the MOS capacitors 201-206 using the drift protection resistors 321-323. In the illustrated configuration, the DC bias voltage at the anodes of the MOS capacitors 201-206 can be controlled to the DC bias voltage of the RF input RF_{IN} and the RF output RF_{OUT}.

Additional details of the variable capacitor cell 450 can be similar to those described earlier.

Although FIGS. 11A-23B illustrate implementations MOS capacitors using n-type MOS (NMOS) capacitors, the teachings herein are also applicable to configurations using p type MOS (PMOS) capacitors.

Additionally, although various embodiments of variable capacitor cells are shown in FIGS. 11A-23B, the teachings herein are also applicable to variable capacitor cells including a different combination of features. For example, to achieve a desired performance for a particular application and/or manufacturing process, a variable capacitor cell can include any suitable combination of features of the embodiments of FIGS. 11A-23B.

### CONCLUSION

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “can,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not only the system described above. The elements and acts of the various embodiments described above can be combined to provide further embodiments.

While certain embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. A power amplifier comprising:
at least a first power amplifier stage coupled with a power supply, said first power amplifier stage configured to adjust a first output power of said first power amplifier stage based on a power supply voltage of said power supply; and
at least a first tunable loadline matching network, said first tunable loadline matching network configured to adjust a loadline value of the power amplifier, said first tunable loadline matching network including at least a first set of metal oxide semiconductor variable capacitor arrays.

2. The power amplifier of claim 1, further comprising a second power amplifier stage.

3. The power amplifier of claim 1, wherein said first tunable loadline matching network is configured to adjust said loadline value of the power amplifier based on said power supply voltage.

4. The power amplifier of claim 2, wherein said first tunable loadline matching network is coupled with an output of said second power amplifier stage.

5. The power amplifier of claim 2, wherein said first tunable loadline matching network is coupled between said first power amplifier stage and said second power amplifier stage.

6. The power amplifier of claim 5, further comprising at least a second tunable loadline matching network.

7. The power amplifier of claim 6, wherein said second tunable matching network is coupled with an output of said second power amplifier stage.

8. The power amplifier of claim 1, wherein said power supply voltage is generated by a battery.

9. The power amplifier of claim 1 further comprising:
at least a second power amplifier stage coupled with said power supply, said second power amplifier stage configured to adjust a second output power of said second power amplifier based on said power supply voltage;
and
at least a second tunable loadline matching network coupled with a second power amplifier stage output of said second power amplifier stage, said second tunable loadline matching network configured to adjust a loadline value of the second power amplifier, said second tunable loadline matching network including at least a second set of metal oxide semiconductor variable capacitor arrays.

10. The power amplifier of claim 1, wherein said at least one first set of metal oxide semiconductor variable capacitor arrays includes at least three variable capacitor cells electrically connected in parallel.

11. The power amplifier of claim 10, wherein each of said at least three variable capacitor cells includes two or more pairs of anti-series metal oxide semiconductor capacitors.

12. A radio-frequency system comprising:
a plurality of power amplifier stages, each of the plurality of power amplifier stages coupled with a power supply, at least a first power amplifier stage of said plurality of power amplifier stages configured to adjust a first output power of said first power amplifier based on said power supply voltage; and
at least a first tunable loadline matching network, said tunable loadline matching network configured to adjust the loadline value of the radio frequency system.

13. The radio frequency system of claim 12, wherein said first tunable loadline matching network is configured to adjust said loadline value based on said power supply voltage.

14. The radio frequency system of claim 12, further comprising a second power amplifier stage of said plurality of power amplifier stages.

15. The radio frequency system of claim 14, wherein said first tunable loadline matching network is coupled with a second output of said second power amplifier stage.

16. The radio frequency system of claim 14, wherein said first tunable loadline matching network is coupled between said first power amplifier stage and said second power amplifier stage.

17. The radio frequency system of claim 12, wherein said first tunable loadline matching network includes at least one first set of metal oxide semiconductor variable capacitor arrays.

18. The radio frequency system of claim 17, wherein said at least one first set of metal oxide semiconductor variable capacitor arrays includes at least three variable capacitor cells electrically connected in parallel.

19. The radio frequency system of claim 18, wherein each of said at least three variable capacitor cells includes two or more pairs of anti-series metal oxide semiconductor capacitors.

20. A radio-frequency system comprising:
a means for amplifying a radio-frequency signal and adjusting an output power based on a power supply voltage, said means for amplifying said radio-frequency signal and adjusting said output power based on said power supply voltage coupled with a power supply; and
a means for adjusting a loadline value coupled with said means for amplifying said radio-frequency signal and adjusting said output power.
